(19) United States
(12) Patent Application Publication
(10) Pub. No.: US 2025/0351702 A1
(43) Pub. Date: Nov. 13, 2025

(54) EMISSIVE DISPLAY DEVICE and ELECTRONIC DEVICE

(71) Applicant: Samsung Display Co., Ltd., Yongin-si (KR)

(72) Inventors: Bokwang SONG, Yongin-si (KR); Gee-Bum KIM, Yongin-si (KR); Hyoeng-Ki KIM, Yongin-si (KR); Kwang Soo BAE, Yongin-si (KR); Byung Han YOO, Yongin-si (KR); Chaun Gi CHOI, Yongin-si (KR)

(21) Appl. No.: 18/987,958

(22) Filed: Dec. 19, 2024

(30) Foreign Application Priority Data
May 7, 2024 (KR) 10-2024-0060147

(51) Int. Cl. H10K 59/80; H10K 59/122; H10K 59/38; H10K 77/10

(52) U.S. Cl. CPC H10K 59/80518; H10K 59/122; H10K 59/38; H10K 59/80515; H10K 59/873; H10K 59/8792; H10K 77/111

(57) ABSTRACT

An emissive display device or an electronic device includes a flexible substrate, an anode positioned on the substrate, a pixel defining layer configured to have a first opening overlapping the anode, a light emitting layer positioned within the first opening of the pixel defining layer and a cathode positioned on the light emitting layer and the pixel defining layer, wherein the anode includes a first anode, which is a reflective electrode, and a second anode, which is a transparent electrode positioned on the first anode, and having a planar area of the second anode which is smaller than a planar area of the first anode in a region overlapping the first opening of the pixel defining layer, and wherein the second anode has a planar structure that is symmetrical with respect to a center of the first opening of the pixel defining layer.

This application claims priority to Korean Patent Application No. 10-2024-0060147, filed on May 7, 2024, and all the benefits accruing therefrom under 35 U.S.C. § 119, the content of which in its entirety is herein incorporated by reference.

### BACKGROUND

### 1. Field

The invention relates to an emissive display device and an electronic device, and more particularly to an emissive display device and an electronic device capable of increasing a luminance ratio.

### 2. Description of the Related Art

A display device operates to display a screen, and may include a liquid crystal display, an organic light emitting diode display, and the like. Such a display device is used in various electronic devices such as mobile phones, navigation units, digital cameras, electronic books, portable game machines, and various terminals.

A display device such as an organic light emitting diode display may have a structure in which the display device can be bent or folded using a flexible substrate.

In addition, in a small electronic device such as a mobile phone, an optical element such as a camera and an optical sensor are formed in a bezel area, which is a periphery of a display area, but a technique capable of positioning a camera or an optical sensor on a rear surface of the display area while increasing a size of a displayed screen and gradually decreasing a size of a surrounding area of the display area is reduced is being developed.

### SUMMARY

An embodiment provides an emissive display device that increases a luminance ratio on a side and has a small rate of change in luminance depending on an angle.

An embodiment provides an emissive display device including a flexible substrate, an anode positioned on the substrate, a pixel defining layer configured to have a first opening overlapping the anode, a light emitting layer positioned within the first opening of the pixel defining layer and a cathode positioned on the light emitting layer and the pixel defining layer, wherein the anode includes a first anode, which is a reflective electrode, and a second anode, which is a transparent electrode positioned on the first anode, and wherein a planar area of the second anode is smaller than a planar area of the first anode in a region overlapping the first opening of the pixel defining layer, and wherein the second anode has a planar structure that is symmetrical with respect to a center of the first opening of the pixel defining layer.

In an embodiment, the second anode may be in direct contact with a portion of the first anode.

In an embodiment, the second anode may overlap the center of the first opening of the pixel defining layer.

In an embodiment, a center of the second anode may coincide with the center of the first opening of the pixel defining layer.

In an embodiment, the first anode may include a metal material, and the second anode may include a metal oxide.

In an embodiment, the second anode may have a thickness of about 50 Å or more and about 500 Å or less.

In an embodiment, the cathode may have a step in an area overlapping the first opening.

In an embodiment, the second anode may overlap the first opening and may not overlap the pixel defining layer.

In an embodiment, at least a portion of the second anode may be covered by a portion of the pixel defining layer.

In an embodiment, the emissive display device may further include an encapsulation layer disposed on the cathode and a light blocking layer or a plurality of color filters positioned on the encapsulation layer and configured to have a second opening that overlaps the first opening in a plan view, and wherein the second opening and the first opening may have the same planar shape.

In an embodiment, the emissive display device may further include an encapsulation layer disposed on the cathode and a light blocking layer or a plurality of color filters positioned on the encapsulation layer and configured to have a second opening that overlaps the first opening in a plan view, and wherein the second opening and the first opening may have different planar shapes.

In an embodiment, the first opening may have one of a circular shape, an oval shape, and a polygonal shape.

In an embodiment, the first opening and the second anode may each be formed in an oval shape, and an oval long axis direction of the first opening may coincide with an oval long axis direction of the second anode.

In an embodiment, the second anode may include a plurality of second anodes that are separated from each other.

In an embodiment, the second anodes, which are separated from each other, may have the same thickness in an area overlapping the first opening.

In an embodiment, one of the plurality of second anodes may be positioned at a center of the first opening, and the remainder of the plurality of second anodes may be positioned along an imaginary circle positioned around the one of the plurality of second anodes.

In an embodiment, the anode, the light emitting layer, and the cathode may constitute one light emitting diode, wherein the light emitting diode may include a first light emitting diode and a second light emitting diode that emits light of different colors, and the second anode included in the first light emitting diode may have a different thickness or width than of the second anode included in the second light emitting diode.

In an embodiment, an area ratio of the second anode to an area of the first anode included in each of the first light emitting diode and the second light emitting diode may be about 0.9 times or more and about 1.1 times or less.

An embodiment provides an emissive display device including a substrate and an anode positioned on the substrate and configured to include a first anode and a second anode, a pixel defining layer configured to have a first opening overlapping the anode, a light emitting layer positioned within the first opening of the pixel defining layer and a cathode positioned on the light emitting layer and the pixel defining layer, wherein the first anode is a reflective electrode, and the second anode is a transparent electrode positioned on the first anode in direct contact with the first anode, wherein a portion of the second anode overlaps the pixel defining layer, and wherein a portion of the first anode is not covered by the second anode in an area overlapping the first opening of the pixel defining layer.

In an embodiment, the second anode may not overlap the center of the first opening of the pixel defining layer.

In an embodiment, the cathode may have a step in an area overlapping the first opening.

In an embodiment, the second anode may include two or more second anodes that are separated from each other.

In an embodiment, the second anode may have a thickness of about 50 Å or more and about 500 Å or less.

In an embodiment, the second anode may have a planar structure that is symmetrical with respect to a center of the first opening of the pixel defining layer.

An embodiment provides an electronic device including an emissive display device, where the emissive display device includes a substrate, wherein the substrate is a flexible substrate; an anode positioned on the substrate; a pixel defining layer configured to have a first opening overlapping the anode; a light emitting layer positioned within the first opening of the pixel defining layer; and a cathode positioned on the light emitting layer and the pixel defining layer, wherein the anode includes, a first anode, which is a reflective electrode; and a second anode, which is a transparent electrode positioned on the first anode and which includes a second anode planar area, wherein the second anode planar area is smaller than a first node planar area in a region overlapping the first opening of the pixel defining layer, and wherein the second anode has a planar structure that is symmetrical with respect to a center of the first opening of the pixel defining layer.

An embodiment provides an electronic device including an emissive display device, wherein the emissive display device comprises: a substrate; an anode positioned on the substrate and configured to include a first anode and a second anode; a pixel defining layer configured to have a first opening overlapping the anode; a light emitting layer positioned within the first opening of the pixel defining layer; and a cathode positioned on the light emitting layer and the pixel defining layer, wherein the first anode is a reflective electrode, and the second anode is a transparent electrode, wherein the second anode is positioned on the first anode to be in direct contact with the first anode, a portion of the second anode overlaps the pixel defining layer, and a portion of the first anode is not covered by the second anode in an area overlapping the first opening of the pixel defining layer.

According to an embodiment, the first electrode included in the light emitting diode may have a step, wherein a step structure may be formed symmetrical with respect to the center of the planar shape of the opening of the pixel defining layer, increasing a luminance ratio on the side and reducing a rate of change in luminance depending on the angle.

According to an embodiment, even if bending occurs in the flexible display devices such as bended or foldable devices, the light emitted from the light emitting diode has a lateral luminance above a certain level and emits light with a low luminance change rate depending on the angle.

### BRIEF DESCRIPTION OF THE DRAWINGS

FIG. 1 illustrates a perspective view showing a use state of a display device, according to an embodiment.

FIG. 2 illustrates an exploded perspective view of a display device, according to an embodiment.

FIG. 3 illustrates a schematic cross-sectional view of a display device, according to an embodiment.

FIG. 4 illustrates a block diagram of a display device, according to an embodiment.

FIG. 5 illustrates a schematic perspective view of an emissive display device, according to an embodiment.

FIG. 6 illustrates a schematic perspective view showing a use state of an emissive display device, according to another embodiment.

FIG. 7 illustrates an exploded perspective view of an emissive display device, according to an embodiment.

FIG. 8 illustrates a schematic perspective view of a display panel, according to another embodiment.

FIG. 9 illustrates a partial top plan view of an emissive display device, according to an embodiment.

FIG. 10 illustrates a schematic cross-sectional view of an emissive display device of FIG. 9, according to an embodiment.

FIG. 11 illustrates a graph for describing an effect of the emissive display device of FIG. 9, according to an embodiment.

FIG. 12 illustrates a graph for describing an effect of the emissive display device of FIG. 9, according to an embodiment.

FIG. 13 illustrates a graph for describing an effect of the emissive display device of FIG. 9, according to an embodiment.

FIG. 14 illustrates a graph for describing an effect of the emissive display device of FIG. 9, according to an embodiment.

FIG. 15 illustrates a graph for describing an effect of the emissive display device of FIG. 9, according to an embodiment.

FIG. 16 illustrates a graph for describing an effect of the emissive display device of FIG. 9, according to an embodiment.

FIG. 17 illustrates a graph for describing an effect of the emissive display device of FIG. 9, according to an embodiment.

FIG. 18 illustrates a graph for describing an effect of the emissive display device of FIG. 9, according to an embodiment.

FIG. 19 illustrates a graph for describing an effect of the emissive display device of FIG. 9, according to an embodiment.

FIG. 20 illustrates a graph for describing an effect of the emissive display device of FIG. 9, according to an embodiment.

FIG. 21 illustrates a cross-sectional view depending on a manufacturing sequence of parts of the emissive display device of FIG. 9, according to an embodiment.

FIG. 22 illustrates a cross-sectional view depending on a manufacturing sequence of parts of the emissive display device of FIG. 9, according to an embodiment.

FIG. 23 illustrates a cross-sectional view depending on a manufacturing sequence of parts of the emissive display device of FIG. 9, according to an embodiment.

FIG. 24 illustrates a cross-sectional view depending on a manufacturing sequence of parts of the emissive display device of FIG. 9, according to an embodiment.

FIG. 25 illustrates a partial top plan view of an emissive display device, according to another embodiment.

FIG. 26 illustrates a schematic cross-sectional view of the emissive display device FIG. 25, according to an embodiment.

FIG. 27 illustrates a partial top plan view of an emissive display device, according to another embodiment.

FIG. 28 illustrates a schematic cross-sectional view of the emissive display device of FIG. 27, according to an embodiment.

FIG. 29 illustrates a graph showing reflectance according to a step difference, according to an embodiment.

FIG. 30 illustrates a schematic cross-sectional view of an emissive display device, according to another embodiment.

FIG. 31 illustrates a partial top plan view of an emissive display device, according to an embodiment.

FIG. 32 illustrates a partial top plan view of an emissive display device, according to an embodiment.

FIG. 33 illustrates a partial top plan view of an emissive display device, according to an embodiment.

FIG. 34 illustrates a partial top plan view of an emissive display device, according to an embodiment.

FIG. 35 illustrates a schematic cross-sectional view of a normal display area and a bending display area of the emissive display device of FIGS. 6 to 8, according to an embodiment.

FIG. 36 illustrates a cross-sectional view of an emissive display device, according to an embodiment.

FIG. 37 illustrates a cross-sectional view of an emissive display device, according to an embodiment.

### DETAILED DESCRIPTION

The invention will be described more fully hereinafter with reference to the accompanying drawings, in which embodiments of the invention are shown. As those skilled in the art would realize, the invention may be modified in various different ways, all without departing from the spirit or scope of the invention.

To clearly describe the invention, parts that are irrelevant to the invention are omitted, and like numerals refer to like or similar components throughout the specification.

Further, since sizes and thicknesses of constituent members shown in the accompanying drawings are arbitrarily given for better understanding and ease of description, the invention is not limited to the illustrated sizes and thicknesses. In the drawings, the thicknesses of layers, films, panels, regions, etc., are exaggerated for clarity. In the drawings, for better understanding and ease of description, the thicknesses of some layers and areas are exaggerated.

It should be understood that when an element such as a layer, film, region, plate, component, etc. is referred to as being “on” another element, it can be directly disposed on the other element or intervening elements may also be present. In contrast, when an element is referred to as being “directly on” another element, there are no intervening elements present. Further, in the specification, the word “on” or “above” means positioned on or below the object portion and does not necessarily mean positioned on the upper side of the object portion based on a gravitational direction.

In addition, unless explicitly stated to the contrary, the word “comprise” and variations such as “comprises” or “comprising” should be understood to imply the inclusion of stated elements but not the exclusion of any other elements.

Further, throughout the specification, the phrase “in a plan view” means when an object portion is viewed from above, and the phrase “in a cross-sectional view” means when a cross-section taken by vertically cutting an object portion is viewed from the side.

In addition, in the specification, “connected” means that two or more components are not only directly connected, but two or more components may be connected indirectly through other components, physically connected as well as being electrically connected, or it may be referred to by different names depending on the location or function, but may include connecting each of parts that are substantially integral to each other.

In addition, throughout the specification, when it is said that a portion of a wire, layer, film, region, plate, component, etc., “extends in a first direction or a second direction,” this does not indicate only a straight shape extending straight in the corresponding direction, and indicates a structure that generally extends along the first direction or the second direction, and it includes a structure that is bent at a portion, has a zigzag structure, or extends while including a curved structure.

In addition, an electronic device (e.g., a mobile phone, TV, monitor, notebook computer, etc.) including a display device, a display panel, etc. described in the specification, or an electronic device including a display device and a display panel manufactured by the manufacturing method described in the specification, are not excluded from the scope of the invention.

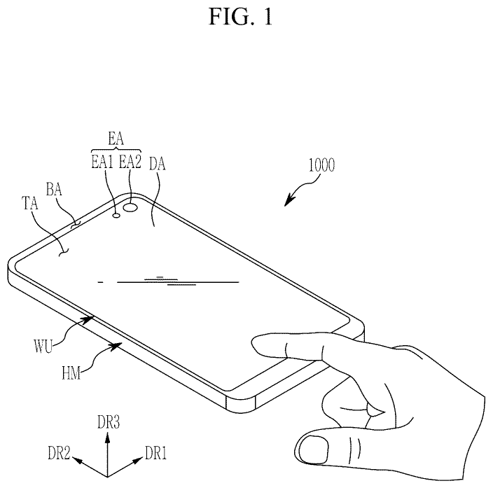

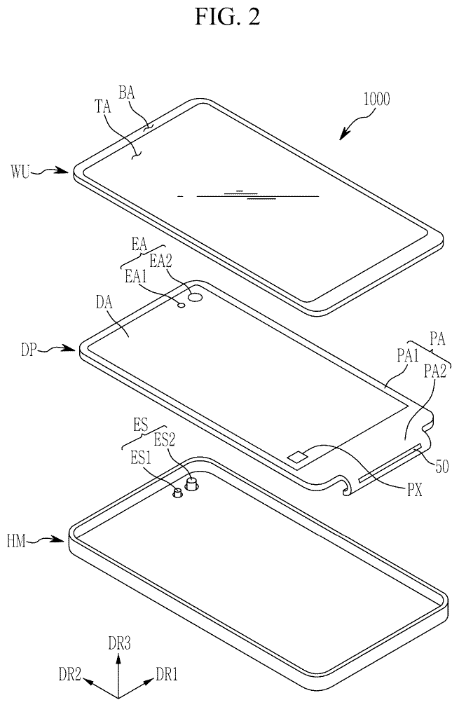

Hereinafter, a schematic structure of a display device will be described in detail with reference to FIG. 1 and FIG. 2.

FIG. 1 illustrates a schematic perspective view showing a use state of a display device, according to an embodiment, and FIG. 2 illustrates an exploded perspective view of a display device, according to an embodiment.

In an embodiment and referring to FIG. 1, the display device 1000, which is a device for displaying a moving image or a still image, may be used as a display screen of various products, such as a television, a laptop computer, a monitor, a billboard, the Internet of things (IOT), etc., as well as portable electronic devices such as a mobile phone, a smart phone, a tablet personal computer, a mobile communication terminal, an electronic notebook, an e-book, a portable multimedia player (PMP), a navigation system, and an ultra-mobile PC (UMPC). In addition, the display device 1000, according to an embodiment, may be used in a wearable device such as a smart watch, a watch phone, a glasses display, or a head-mounted display (HMD). In addition, the display device 1000, according to an embodiment, may be used as an instrument panel of a vehicle, a center information display (CID) provided at a center fascia or dashboard of a vehicle, a room mirror display that replaces a side mirror of a vehicle, or a display provided on a back surface of a front seat of a vehicle. FIG. 1 illustrates that the display device 1000 is used as a smart phone for convenience of description.

In an embodiment, the display device 1000 may display an image in a third direction DR3 on a display surface directed parallel to each of a first direction DR1 and a second direction DR2. A display surface on which an image is displayed may correspond to a front surface of the display device 1000 and may correspond to a front surface of a cover window WU. The image may include a still image as well as a dynamic image.

In an embodiment, a front surface (or upper surface) and a rear surface (or lower surface) of each member are defined based on a direction in which the image is displayed. The front and rear surfaces may be disposed opposite to each other in the third direction DR3, and a normal direction of each of the front and rear surfaces may be directed parallel to the third direction DR3. A distance between the front surface and the rear surface in the third direction DR3 may correspond to a thickness of the display panel in the third direction DR3.

In an embodiment, the display device 1000 may sense a user input (refer to a hand in FIG. 1) applied from the outside, where the user input may include various types of external inputs, such as a part of a user's body, light, heat, or pressure. In an embodiment, the user input is illustrated as a user hand applied to the front surface. However, the invention is not limited thereto. The user input may be provided in various forms, and in addition, the display device 1000 may sense the user input applied to the side surface or the rear surface of the display device 1000 depending on a structure of the display device 1000.

In an embodiment and referring to FIG. 1 and FIG. 2, the display device 1000 may include a cover window WU, a housing HM, a display panel DP, and an optical element ES. In an embodiment, the cover window WU and the housing HM may be combined to form an outer appearance of the display device 1000.

In an embodiment, the cover window WU may include an insulating panel, where the cover window WU may be formed of glass, plastic, or a combination thereof.

A front surface of the cover window WU may define a front surface of the display device 1000. A transmissive area TA may be an optically transparent area and may be an area having visible ray transmittance of about 90% or more.

A blocking area BA defines a shape of the transmissive area TA, where the blocking area BA may be disposed adjacent to the transmissive area TA, to surround the transmissive area TA. The blocking area BA may be an area having relatively low light transmittance compared to the transmissive area TA. The blocking area BA may include an opaque material that blocks light. The blocking area BA may have a predetermined color. The blocking area BA may be defined by a bezel layer provided separately from a transparent substrate defining the transmissive area TA or may be defined by an ink layer formed by being inserted or colored in a transparent substrate.

In an embodiment, the display panel DP may include a display pixel PX that displays an image and a driver 50, where the display pixel PX is positioned in a display area DA and a component area EA. The display panel DP may include a front surface including a display area DA and a peripheral area PA. In an embodiment, the display area DA and the component area EA are areas in which an image is displayed by including pixels and may be areas where a touch sensor is positioned above the pixel in the third direction DR3 to sense an external input.

In an embodiment, a transmissive area TA of the cover window WU may at least partially overlap the display area DA and the component area EA of the display panel DP. For example, the transmissive area TA may overlap an entire surface of the display area DA and the component area EA, or may at least partially overlap the display area DA and the component area EA. Accordingly, a user may view an image through the transmissive area TA or may provide an external input based on the image. However, the invention is not limited thereto. For example, an area in which an image is displayed and an area in which the external input is sensed may be separate from each other.

In an embodiment, the peripheral area PA of the display panel DP may at least partially overlap a blocking area BA of the cover window WU. The peripheral area PA may be an area covered by a blocking area BA. The peripheral area PA may be disposed adjacent to the display area DA, and may surround the display area DA. An image is not displayed in the peripheral area PA, and a driving circuit, a driving wire, and the like may be arranged to drive the display area DA. The peripheral area PA may include a first peripheral area PA1 in which the display area DA is positioned outside and a second peripheral area PA2 including a driver 50, and a connection wire, and a bending area. In the embodiment of FIG. 2, the first peripheral area PA1 is positioned at a third side of the display area DA and the second peripheral area PA2 is positioned at a remaining side of the display area DA.

In an embodiment, the display panel DP may be assembled in a flat state in which the display area DA, the peripheral area PA, and the component area EA face the cover window WU. However, the invention is not limited thereto. A portion of the peripheral area PA of the display panel DP may be bent. In this case, a portion of the peripheral area PA faces the rear surface of the display device 1000, so that the blocking area BA shown on the front surface of the display device 1000 may be reduced, and in FIG. 2, the second peripheral area PA2 may be bent to be positioned on the rear surface of the display area DA, and then assembled.

In addition, the display panel DP may include the component area EA having a first component area EA1 and a second component area EA2, where the first component area EA1 and the second component area EA2 may be at least partially surrounded by the display area DA. Although the first component area EA1 and the second component area EA2 are illustrated as being spaced apart from each other, the invention is not limited thereto, and at least portions thereof may be connected. The first component area EA1 and the second component area EA2 may be areas in which an optical element (see ES in FIG. 2 and hereinafter referred to as a component) that uses infrared rays, visible light, or audio is positioned.

In an embodiment, the display area DA (hereinafter also referred to as a main display area) and the component area EA are formed with a plurality of light emitting diodes and a plurality of pixel circuit units that generate and transmit a light emitting current to each of the light emitting diodes. Herein, one light emitting diode and one pixel circuit unit are referred to as a pixel PX. One pixel circuit unit and one light emitting diode may be formed one-to-one in the display area DA and the component area EA.

In an embodiment, the first component area EA1 may include a transmissive portion through which light and/or audio may pass and a display unit including a plurality of pixels. The transmissive portion is positioned between adjacent pixels and is formed include a layer through which light and/or audio can pass. The transmissive portion may be positioned between adjacent pixels, and a layer through which light is not transmitted, such as a light blocking layer, may overlap the first component area EA1. A number of pixels per unit area of pixels (hereinafter also referred to as normal pixels) included in the display area DA (hereinafter referred to as resolution) and a number of pixels per unit area of pixels (hereinafter also referred to as first component pixels) included in the first component area EA1 may be the same.

In an embodiment, the second component area EA2 may include an area (hereinafter also referred to as a light transmitting area) including a transparent layer to allow light to pass therethrough, no conductive layer or semiconductor layer may be positioned in the light transmitting area, and the light transmitting area may have a structure that does not block light by having an opening that overlaps a position where a layer including a light blocking material—e.g., a pixel defining layer and/or a light blocking layer—corresponds to the second component area EA2. A number of pixels per unit area of the pixels (hereinafter also referred to as second component pixels) included in the second component area EA2 may be smaller than a number of pixels per unit area of the normal pixels included in the display area DA. As a result, resolution of the second component pixels may be lower than that of the normal pixels.

In an embodiment, the display panel DP may further include a touch sensor in addition to the display area DA including the display pixels PX. The display panel DP may be visually recognized by a user from the outside through the transmissive area TA, including pixels PX that generate an image. In addition, the touch sensor may be positioned above the pixels PX and may sense an external input applied from the outside. The touch sensor may sense the external input provided to the cover window WU.

In an embodiment and referring to FIG. 2, a second peripheral area PA2 may include a bending portion. The display area DA and the first peripheral area PA1 may have a flat state that is directed substantially parallel to a plane defined by the first direction DR1 and the second direction DR2, and a first side of the second peripheral area PA2 may extend from the flat state and have the flat state again after going through a bending portion. As a result, at least a portion of the second peripheral area PA2 may be bent and assembled to be positioned on a back side of the display area DA. At least a portion of the second peripheral area PA2 overlaps the display area DA in a plan view when assembled, so that the blocking area BA of the display device 1000 may be reduced. However, the invention is not limited thereto. For example, the second peripheral area PA2 may not be bent.

In an embodiment, the driver 50 may be mounted on the second peripheral area PA2 and may be mounted on the bending portion or positioned at one of opposite sides of the bending portion. The driver 50 may be provided in the form of a chip.

The driver 50 may be electrically connected to the display area DA and the component area EA to transmit electrical signals to pixels in the display area DA and the component area EA. For example, the driver 50 may provide data signals to the pixels PX positioned in the display area DA. In another embodiment, the driver 50 may include a touch driving circuit, and may be electrically connected to the touch sensor positioned in the display area DA and the component area EA. Meanwhile, the driver 50 may include various circuits in addition to the above-described circuits, or may be designed to provide various electrical signals to the display area DA.

In an embodiment, the display device 1000 may include a pad portion positioned at an end of the second peripheral area PA2 and may be electrically connected to a flexible printed circuit board (FPCB) including a driving chip by means of a pad portion. Herein, the driving chip positioned on the flexible printed circuit board may include various driving circuits for driving the display device 1000, connectors for supplying power, etc. According to an embodiment, a rigid printed circuit board (PCB) may be used instead of the flexible printed circuit board.

In an embodiment, an optical element ES may be positioned at a lower portion of the display panel DP, where the optical element ES may include a first optical element ES1 overlapping the first component area EA1 and a second optical element ES2 overlapping the second component area EA2. The first optical element ES1 may use infrared rays, and in this case, a layer that does not transmit light, such as a light blocking layer, may overlap the first component area EA1.

In an embodiment, the first optical element ES1 may be replaced with an electronic element that uses light or audio. For example, the first optical element ES1 may be replaced with a sensor that receives and uses light, such as an infrared sensor, a sensor that outputs and detects light or audio to measure a distance or to recognize fingerprints, a small lamp that outputs light, a speaker that outputs audio, or the like. Of course, in the case of an electronic element using light, light of various wavelength bands such as visible light, infrared light, and ultraviolet light may be used.

In an embodiment, the second optical element ES2 may be at least one of a camera, an infrared camera, a dot projector, an infrared illuminator, or a time-of-flight sensor.

In an embodiment and referring to FIG. 2, the housing HM may be coupled to the cover window WU, where the cover window WU may be disposed on the front of the housing HM. The housing HM may be coupled to the cover window WU to provide a predetermined accommodation space. The display panel DP and the optical element ES may be accommodated in the predetermined accommodation space provided between the housing HM and the cover window WU.

The housing HM may include a material having relatively high rigidity. For example, the housing HM may include a plurality of frames and/or plates made of glass, plastic, metal, or a combination thereof. The housing HM may stably protect components of the display device 1000 accommodated in an internal space from external impact.

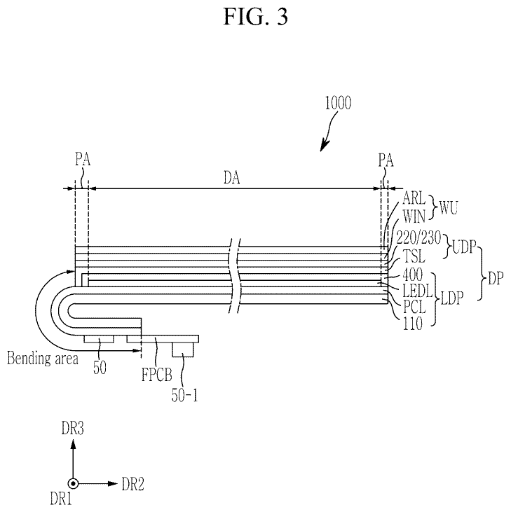

In an embodiment, the emissive display device described above may have a cross-sectional structure as shown in FIG. 3, and the cross-sectional structure will be described through FIG. 3.

FIG. 3 illustrates a schematic cross-sectional view of a display device, according to an embodiment.

In an embodiment and referring to FIG. 3, the emissive display device 1000 includes a display panel DP roughly divided into a lower panel layer LDP and an upper panel layer UDP and a cover window WU positioned on a front surface of the display panel.

In an embodiment, the lower panel layer LDP of the display panel DP may have a light emitting device layer LEDL where the light emitting diodes constituting the pixels PX are positioned on a flexible substrate 110, and a pixel circuit layer PCL where a pixel circuit unit that transmits a current to a light emitting diode positioned on the light emitting device layer LEDL is positioned, and the pixel circuit layer PCL may be positioned between the substrate 110 and the light emitting device layer LEDL. The lower panel layer LDP further includes an encapsulation layer 400, where the light emitting device layer LEDL is covered by the encapsulation layer 400. By the action of the encapsulation layer 400, the light emitting device layer LEDL may be protected by preventing moisture and air from flowing into the light emitting device layer LEDL.

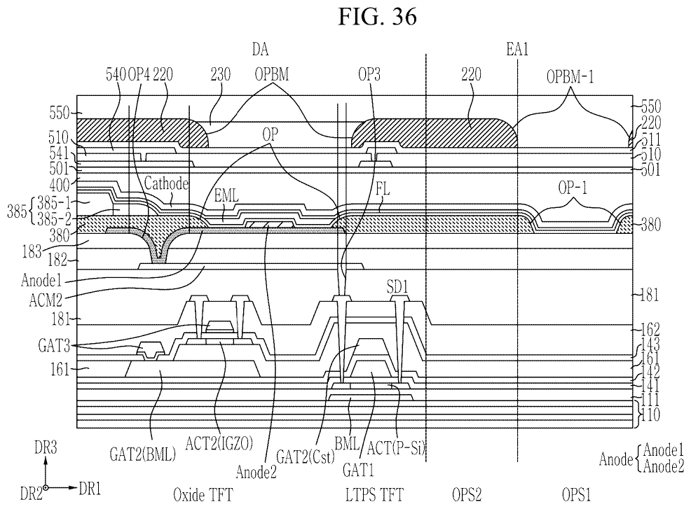

In an embodiment, the upper panel layer UDP of the display panel DP may include a touch sensing layer TSL, a light blocking layer 220, and a color filter 230. The touch sensing layer TSL may include a sensing insulating layer (refer to 501, 510, and 511 in FIG. 36) and a plurality of sensing electrodes (refer to 540 and 541 in FIG. 36). The light blocking layer 220 and the color filter 230 may include a light blocking layer (see 220 in FIG. 36) and a color filter (see 230 in FIG. 36).

Each structure will be described in detail as follows.

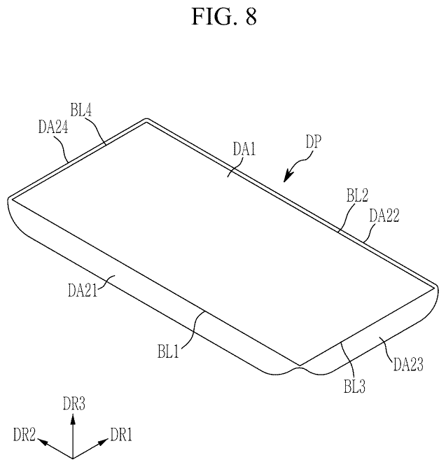

In an embodiment, the substrate 110, which is a base substrate or a base member, may be a flexible substrate capable of being bent, folded, or rolled. For example, the substrate 110 may include a polymer resin such as polyimide (PI), but the present disclosure is not limited thereto. In another embodiment, the substrate 110 may include a glass material or a metal material. Although the display panel DP is shown in a flat shape in FIG. 3, a portion (e.g., an edge portion) may be bent as shown in FIG. 8, and the display area DA may have a folded or bent structure.

In an embodiment, the pixel circuit layer PCL may be disposed on the substrate 110, where the pixel circuit layer PCL may include a plurality of thin-film transistors constituting the pixel circuit unit of the pixel PX, and may additionally include a capacitor. The pixel circuit layer PCL may include wiring connected to the pixel circuit unit, including a scan line, a data line, and a power voltage line. Each of the thin-film transistors may include a semiconductor region, a source electrode, a drain electrode, and a gate electrode. The pixel circuit layer PCL may be disposed in the display area DA, and, according to another embodiment, it may also be positioned in a portion of the peripheral area PA or a portion of the bending area.

In an embodiment, the light emitting device layer LEDL may be disposed on the pixel circuit layer PCL and may include a plurality of light emitting diodes that emit light, including an anode, a cathode, and a light emitting layer, and a pixel defining layer that defines a light emitting area. The light emitting devices of the light emitting device layer LEDL may be positioned in the display area DA.

In an embodiment, the light emitting layer may be an organic light emitting layer containing an organic material. The light emitting layer may include at least one functional layer such as a hole transport layer, a hole transfer layer, an electron transport layer, and an electron transfer layer thereabove or therebelow. When a current flows between the anode and the cathode, holes and electrons may move to the light emitting layer through the hole transport layer and electron transport layer, respectively, and may combine with each other in the light emitting layer to emit light.

According to another embodiment, the light emitting device may include a quantum dot light emitting diode including a quantum dot light emitting layer, an inorganic light emitting diode including an inorganic semiconductor, or a micro-light emitting diode.

In an embodiment, the encapsulation layer 400 may cover upper and side surfaces of the light emitting device layer LEDL and may protect the light emitting device layer LEDL. The encapsulation layer 400 may include at least one inorganic layer and at least one organic layer to encapsulate the light emitting device layer LEDL.

In an embodiment, the touch sensing layer TSL may be disposed on the encapsulation layer 400 and may include a plurality of sensing electrodes for detecting a user touch in a capacitance manner, and a plurality of sensing lines connecting the sensing electrodes and a touch driver 50-1. According to another embodiment, the touch sensing layer TSL may detect the user touch using a mutual capacitance method or a self-capacitance method.

According to another embodiment, the touch sensing layer TSL may be disposed on a separate substrate positioned on the light emitting device layer LEDL. In this case, a substrate supporting the touch sensing layer TSL may serve as an encapsulation substrate that encapsulates the light emitting device layer LEDL, and when the encapsulation substrate is positioned, the encapsulation layer 400 may be omitted.

In an embodiment, the sensing electrodes of the touch sensing layer TSL may not overlap the light emitting area, and may be covered with a light blocking layer, etc., which will be described later.

In an embodiment, the light blocking layer 220 and the color filter 230 are disposed on the touch sensing layer TSL and may include a light blocking layer (see 220 in FIG. 36) and a color filter (see 230 in FIG. 36). The light blocking layer may cover the sensing electrode and may have a position that does not overlap the light emitting area, and the color filter may improve the color of the light emitted from the light emitting diode by overlapping the light emitting area to which each color filter corresponds.

The light blocking layer 220 and the color filter 230 may have a structure that reduces reflection of external light to prevent external light flowing into the display device 1000 from being reflected again and transmitted to a user's eyes.

In an embodiment, the substrate 110 may have a structure folded toward a back surface including a bending area, and the driver 50 may be positioned on a first surface of the folded substrate 110 and may be electrically connected to a circuit board FPCB to which the touch driver 50-1 is attached.

In an embodiment, the driver 50 may output signals and voltages for driving the display panel DP and may supply data voltages to a plurality of data lines, may supply respective power voltages to power lines such as driving voltage lines, and may supply control signals such as clock signals to generate scan signals to be applied to scan lines. The driver 50 may be formed of an integrated circuit (IC) to be mounted in the display panel DP using a chip on glass (COG) method, a chip on plastic (COP) method, or an ultrasonic bonding method. For example, the driver 50 may be positioned in a direction opposite to the display area DA and the third direction DR3 by bending the substrate 110, and may be positioned on the back surface of the display area DA. According to another embodiment, the driver 50 may be mounted on the circuit board FPCB.

In an embodiment, the circuit board FPCB may be attached to a pad portion of the display panel DP using an anisotropic conductive film (ACF). The pad portion of the circuit board FPCB may be electrically connected to the pad portion of the display panel DP. The circuit board FPCB may be a flexible printed circuit board, a printed circuit board, or a flexible film such as a chip on film.

In an embodiment, the touch driver 50-1 may be mounted on the circuit board FPCB. The touch driver 50-1 may be electrically connected to the sensing electrodes of the touch sensing layer TSL of the display panel DP to supply driving signals to the sensing electrodes and may determine whether a touch is present by detecting an amount of change in capacitance between the sensing electrodes. The touch driver 50-1 may be formed of an integrated circuit (IC).

In an embodiment, the cover window WU may be positioned on the front surface of the display panel DP, and the cover window WU may include a window WIN and an anti-reflection layer ARL.

In an embodiment, the window WIN may be positioned on the light blocking layer 220 and the color filter 230, and may be attached to the light blocking layer 220 and the color filter 230 using a transparent adhesive. The window WIN may serve to protect the display panel DP and may be made of a transparent material. The window WIN may include, for example, glass or plastic.

In an embodiment, when the window WIN includes glass, the glass may be ultra-thin glass (UTG) or thin-film glass. The ultra-thin glass may be strengthened to have a predetermined stress profile within it. Tempered ultra-thin glass prevents cracks from occurring, propagating, and breaking due to external impacts better than before tempering. Ultra-thin glass strengthened through a tempering process may have varying stresses in each area.

When glass is made of an ultra-thin film or a thin film, it may have a flexible characteristic to be curved, bent, folded, or rolled. A thickness of the glass may range from, for example, about 10 μm to about 300 μm, and specifically, glass with a thickness of about 10 μm to about 100 μm or about 50 μm may be applied. Glass of the window WIN may include soda lime glass, alkali aluminosilicate glass, borosilicate glass, or lithium aluminosilicate glass. The glass of the window WIN may include chemically strengthened or thermally strengthened glass to have enhanced strength.

Chemical strengthening may be achieved through an ion exchange treatment process in alkaline salts. The ion exchange treatment process may be performed two or more times. Additionally, the window WIN may be a polymer film coated with a thin film of glass at opposite sides.

In an embodiment, an anti-reflection layer ARL may be positioned on a front surface of the window WIN, and the anti-reflection layer ARL may be attached to the front surface of the window WIN in the form of an optical film.

The anti-reflection layer ARL may be disposed on the window WIN and may protect the window WIN and may reduce reflection of external light.

In an embodiment, the anti-reflection layer ARL may include a hard coating layer and a low-refractive index layer, and may prevent or reduce reflection of external light by forming two layers with different refractive indices so that external light is lost or offsetting interference occurs. Herein, the low-refractive index layer may have a structure including particles dispersed in a transparent resin. Meanwhile, according to another embodiment, a high-refractive index layer may be additionally included, and the high-refractive index layer may be positioned between the hard coating layer and the low-refractive index layer.

In an embodiment, the hard coating layer, the low-refractive index layer, and/or the high-refractive index layer that may be included in the anti-reflection layer ARL may have the following characteristics.

In an embodiment, the hard coating layer may reduce distortion or lifting of the anti-reflection layer ARL under a harsh condition such as high temperature and high humidity, thereby ameliorating reliability issues.

In an embodiment, the hard coating layer may include an organic layer, where the organic layer may include at least one of an acrylate-based compound, a urethane-based compound, polyimide, polycarbonate, polyethersulfone, polyethylene naphthalate, polyphenylene sulfide, a liquid crystal polymer (LCP), polymethyl methacrylate, or an epoxy polymer, or a combination thereof.

In another embodiment, the hard coating layer may include an organic layer and an organic-inorganic composite layer. In this embodiment, the organic layer may include an acrylate-based compound. For example, the organic layer may be formed including urethane acrylate. The organic layer may serve as a stress buffer layer.

In an embodiment, an organic material in the organic-inorganic composite layer may be formed from at least one of an acrylate-based compound, a polyurethane-based compound, or an epoxy-based compound, or a combination thereof. For example, the organic material may include urethane acrylate. In the organic-inorganic composite layer, an inorganic material may be at least one of a silicon oxide (SiO2), a zirconium oxide (ZrO2), an aluminum oxide (Al2O3), a tantalum oxide (Ta2O5), niobium oxide (Nb2O5 or NbO2) or glass beads.

In an embodiment, the inorganic material may be provided in the form of a single type of inorganic oxide listed above or a mixture thereof. Additionally, inorganic materials may be provided in various forms to form an organic-inorganic composite layer. For example, a silicon oxide may be provided in the form of particles, sols, or hollow shapes.

In an embodiment, in the organic-inorganic composite layer, an organic acrylate compound and inorganic particles may be mixed at a weight ratio of about 5:5 to about 8:2. By containing both the acrylate compound and the inorganic particles, the organic-inorganic composite layer may improve surface hardness and may provide shock absorbency against external shock, forming a hard coating layer that is not easily broken.

In an embodiment, the hard coating layer may include an acrylate-based compound and a urethane-based compound. The acrylate-based compound and the urethane-based compound may be mixed in monomer form to be polymerized. The acrylate-based compound may increase hardness and wear resistance of the anti-reflection layer ARL by increasing hardness of the low-refractive index layer. The urethane-based compound may increase elasticity of the anti-reflection layer ARL by providing flexibility to the low-refractive index layer. In this case, a proportion of the acrylate-based compound in the hard coating layer may be about 70% to about 99.9%, and a proportion of the urethane-based compound may be about 0.1% to about 30%. For example, a mixing ratio of the acrylate-based compound and a urethane-based compound may be about 7:3 or more, and a ratio of the acrylate-based compound may be further increased. For example, the mixing ratio of the acrylate-based compound and the urethane-based compound may be further increased, such as about 7:3, about 8:2, or about 9:1.

In another embodiment, the hard coating layer may include an acrylate-based compound. In this case, the acrylate-based compound may be an acrylic resin. That is, the hard coating layer may improve hardness and wear resistance of the anti-reflection layer ARL by including the acrylic resin.

In an embodiment, a thickness of the hard coating layer may be about 2 μm to about 10 μm. By having the hard coating layer within the above thickness range, distortion or lifting phenomena may be reduced, ameliorating reliability problems.

In an embodiment, a refractive index of the hard coating layer may be in a range of about 1.48 to about 1.53. The hard coating layer may be made in the above refractive index range, so it has a difference in refractive index at an interface with the low-refractive index layer, which will be described later, so as to refract light emitted from the light emitting device layer upward to increase light output efficiency and reduce reflection of external light.

In an embodiment, the low-refractive index layer may be disposed on the hard coating layer and may refract the light emitted from the light emitting device layer upward to increase light output efficiency and reduce reflection of external light.

The low-refractive index layer may include particles dispersed in a transparent resin.

In an embodiment, the resin may include one or more of acryl, polysiloxane, polyurethane, polyurethane acrylate, polyimide, polymethylsilsesquioxane (PMSSQ), and poly(methyl methacrylate) (PMMA).

In an embodiment, the particles may be hollow particles. For example, the particles may be one or more of silica (SiO2), magnesium fluoride (MgF2), and iron oxide (Fe3O4). Additionally, the particles may include a shell made of one or more of the above materials and a hollow interior of the shell. In an embodiment, a diameter of the particle may be about 10 to about 200 nm, and a thickness of the shell and a diameter of the hollow shell may be determined depending on the diameter of the particle.

In an embodiment, particles included in the low-refractive index layer may be included in a weight ratio of about 10% to about 50% relative to the resin. If the weight ratio of the particles to the resin is about 10% or more, a refractive index of the low-refractive index layer may be lowered, and if it is about 50% or less, the adhesion to adjacent layers may be prevented from being reduced. The low-refractive index layer may be formed by coating and curing a solution containing a solvent in which resins and particles are dispersed.

In an embodiment, a thickness of the low-refractive index layer may be about 10 to about 200 nm. By having the low-refractive index layer within the above thickness range, it may contain sufficient particles to lower the refractive index and improve adhesion to the lower layer.

In an embodiment, the refractive index of the low-refractive index layer may be smaller than the refractive index of the hard coating layer. For example, the refractive index of the low-refractive index layer may be about 0.05 or more smaller than the refractive index of the hard coating layer. If a difference between the refractive index of the low-refractive index layer and the refractive index of the hard coating layer is about 0.05 or more, total reflection of external light may be increased at an interface between the low-refractive index layer and the hard coating layer, leading to destructive interference with light reflected from the surface of the low-refractive index layer. Accordingly, the reflectance of external light of the anti-reflection layer ARL may be reduced. The refractive index of the low-refractive index layer may be in a range of about 1.3 to about 1.43. However, the invention is not limited thereto, and a lower refractive index may be used within a range smaller than the refractive index of the hard coating layer.

In an embodiment, the high-refractive index layer may include an inorganic material, an organic material, or an inorganic material and an organic material. Accordingly, the high-refractive index layer may be made of an inorganic film, an organic film, or an organic film containing inorganic particles.

In an embodiment, an inorganic material contained in the high-refractive index layer may include one or more of a zinc oxide, a titanium oxide, a zirconium oxide, a niobium oxide, a tantalum oxide, a tin oxide, a nickel oxide, a silicon oxide, a silicon nitride, an indium nitride, and a gallium nitride.

In an embodiment, an organic material contained in the high-refractive index layer may include one or more of poly (3,4-ethylenedioxythiophene), PEDOT), 4,4′-bis[N-(3-methylphenyl)-N-phenylamino]biphenyl (TPD), 4,4′,4″-tris[(3-methylphenyl) phenyl aminotriphenylamine (m-MTDATA), 1,3,5-tris[N,N-bis(2-methylphenyl)-amino]-benzene (o-MTDAB), 1,3,5-tris[N,N-bis(3-methylphenyl)-amino]-benzene (m-MTDAB), 1,3,5-tris[N,N-bis(4-methylphenyl)-amino]-benzene (p-MTDAB), 4,4′-bis[N,N-bis(3-methylphenyl)-amino]-diphenylmethane (BPPM), 4,4′-dicarbazolyl-1,1′-biphenyl (CBP), 4,4′,4″-tris (N-carbazole) triphenylamine (TCTA), 2,2′,2″-(1,3,5-benzentolyl)tris-[1-phenyl-1H-benzoimidazole](TPBI), and 3-(4-biphenyl)-4-phenyl-5-t-butylphenyl-1,2,4-triazole (TAZ).

In an embodiment, the refractive index of the high-refractive index layer may be greater than that of the low-refractive index layer to reduce reflection of external light. For example, the refractive index of the high-refractive index layer may be about 0.05 or more greater than the refractive index of the low-refractive index layer. The refractive index of the high-refractive index layer may be in a range of about 1.53 to about 1.7. However, the invention is not limited thereto, and a greater refractive index may be used within a range larger than the refractive index of the low-refractive index layer.

In an embodiment, a thickness of the high-refractive index layer may be about 50 to about 500 nm. By having the high-refractive index layer within the above thickness range, the interface with the low-refractive index layer may be formed flat, and a bonding strength with the hard coating layer may be prevented from decreasing.

In an embodiment, the anti-reflection layer ARL further including a high-refractive index layer may further reduce reflection of external light by increasing a difference in refractive index at an interface with the low-refractive index layer.

According to another embodiment, an optical film other than the anti-reflection layer ARL may be further included on a front surface of the window WIN, and an anti-fingerprint layer may be included. However, a polarizing plate is not included, and this is because the light blocking layer 220 and the color filters 230, which will be described later, lower reflectance of external light and make it difficult for a user to see. Accordingly, in still another embodiment, the anti-reflection layer ARL may not be included on the front surface of the window WIN.

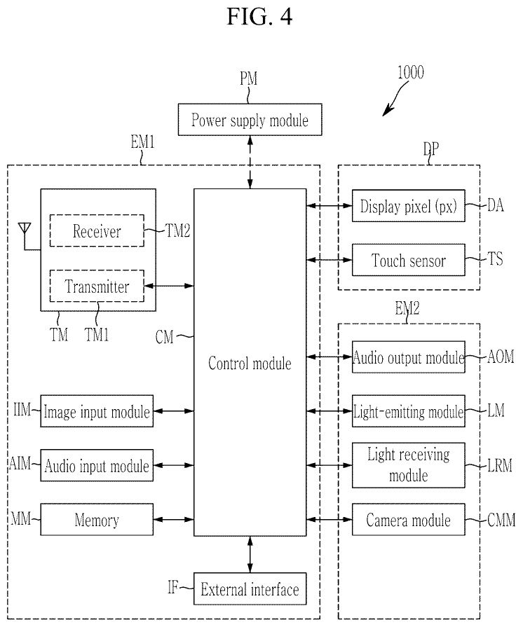

Hereinafter, a display device according to an embodiment will be described through a block-by-block illustration using FIG. 4.

FIG. 4 illustrates a block diagram of a display device, according to an embodiment.

In an embodiment and referring to FIG. 4, the display device 1000 may include a display panel DP, a power supply module PM, a first electronic module EM1, and a second electronic module EM2. The display panel DP, the power supply module PM, the first electronic module EM1, and the second electronic module EM2 may be electrically connected to each other. In FIG. 4, a display pixel and a touch sensor TS positioned in the display area DA among elements of the display panel DP are illustrated as an example.

In an embodiment, the power supply module PM may supply power required for overall operation of the display device 1000 and may include a conventional battery module.

In an embodiment, the first electronic module EM1 and the second electronic module EM2 may include various functional modules for operating the display device 1000. The first electronic module EM1 may be directly mounted on a motherboard that is electrically connected to the display panel DP or may be mounted on a separate board to be electrically connected to the motherboard through a connector (not illustrated).

In an embodiment, the first electronic module EM1 may include a control module CM, a wireless communication module TM, an image input module IIM, an audio input module AIM, a memory MM, and an external interface IF. Some of the modules may not be mounted to a motherboard, but may be electrically connected to the motherboard through a flexible printed circuit board connected thereto.

In an embodiment, the control module CM may control the overall operation of the display device 1000. The control module CM may be a microprocessor. For example, the control module CM activates or deactivates the display panel DP. The control module CM may control other modules such as the image input module IIM and the audio input module AIM based on a touch signal received from the display panel DP.

In an embodiment, the wireless communication module TM may transmit/receive a wireless signal to/from another terminal using a Bluetooth or Wi-Fi line. The wireless communication module TM may transmit/receive a voice signal using a general communication line. The wireless communication module TM includes a transmitter TM1 that modulates and transmits a signal to be transmitted, and a receiver TM2 that demodulates the received signal.

In an embodiment, the image input module IIM may process an image signal and may convert it into image data that can be displayed on the display panel DP. The audio input module AIM may receive an external audio signal by a microphone in a recording mode, a voice recognition mode, and the like, and may convert it into electrical voice data.

In an embodiment, the external interface IF may serve as an interface connected to an external charger, a wired/wireless data port, a card socket (e.g., a memory card, a SIM/UIM card), and the like.

In an embodiment, the second electronic module EM2 may include an audio output module AOM, a light emitting module LM, a light receiving module LRM, and a camera module CMM, etc., at least some of which are optical elements ES, which may be positioned on the rear surface of the display panel DP as illustrated in FIG. 1 and FIG. 2. The optical element ES may include a light emitting module LM, a light receiving module LRM, and a camera module CMM. In addition, the second electronic module EM2 may be mounted directly on the motherboard, may be mounted on a separate board, and may be electrically connected to the display panel DP through a connector (not illustrated) or the like, or may be electrically connected to the first electronic module EM1.

In an embodiment, the audio output module AOM may convert audio data received from the wireless communication module TM or audio data stored in the memory MM to output the converted audio data to the outside.

In an embodiment, the light emitting module LM may generate and output light. The light emitting module LM may output infrared rays. For example, the light emitting module LM may include an LED element. Additionally, the light receiving module LRM may sense infrared rays, where the light receiving module LRM may be activated when infrared rays of a predetermined level or more are sensed. Moreover, the light receiving module LRM may include a CMOS sensor. After infrared light generated by the light emitting module LM is output, it is reflected by an external subject (e.g., a user's finger or face), and the reflected infrared light may be incident on the light receiving module LRM. The camera module CMM may capture an external image.

In an embodiment, the optical element ES may additionally include a photosensitive sensor or a thermal sensor and may sense an external object received through the front surface or may supply an audio signal such as a voice through the front surface to the outside. In addition, the optical element ES may include a plurality of components, but is not limited to any one embodiment.

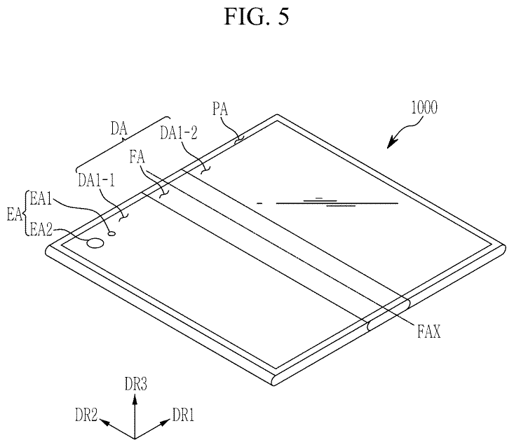

Hereinafter, a structure of the display device 1000 with a foldable characteristic will be described with reference to FIG. 5.

FIG. 5 illustrates a schematic perspective view of an emissive display device, according to an embodiment.

Descriptions of the same components as those described above will be omitted, and the embodiment of FIG. 5 shows a foldable display device in which the display device 1000 is folded through a folding axis FAX.

In an embodiment and referring to FIG. 5, the display device 1000 may be a foldable display device

In an embodiment, the display device 1000 may be folded outwardly or inwardly based on the folding axis FAX. When folded outwardly based on the folding axis FAX, display surfaces of the display device 1000 are positioned outside in the third direction DR3 to display images in opposite directions. When folded inwardly based on the folding axis FAX, the display surfaces may not be visually recognized from the outside.

In an embodiment, the display device 1000 may include a display area DA, a component area EA, and a peripheral area PA. The display area DA may be divided into a first-1 display area DA1-1, a first-2 display area DA1-2, and a folding area FA. The first-1 display area DA1-1 and the first-2 display area DA1-2 may be positioned at the left and right sides, respectively, with respect to (or at the center of) the folding axis FAX, and the folding area FA may be positioned between the first-1 display area DA1-1 and the first-2 display area DA1-2. In this embodiment, when folded outwardly based on the folding axis FAX, the first-1 display area DA1-1 and the first-2 display area DA1-2 may be positioned at opposite sides in the third direction DR3, and images may be displayed in both directions. In addition, when folded inwardly based on the folding axis FAX, the first-1 display area DA1-1 and the first-2 display area DA1-2 may not be viewed from the outside.

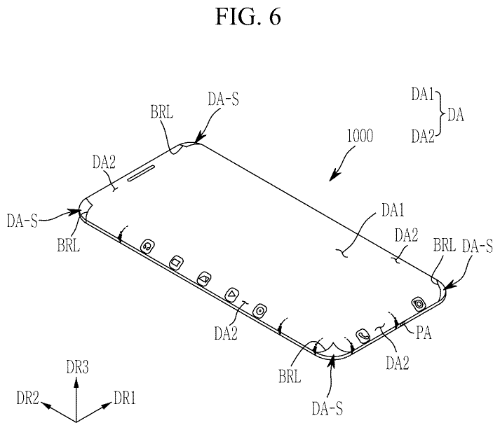

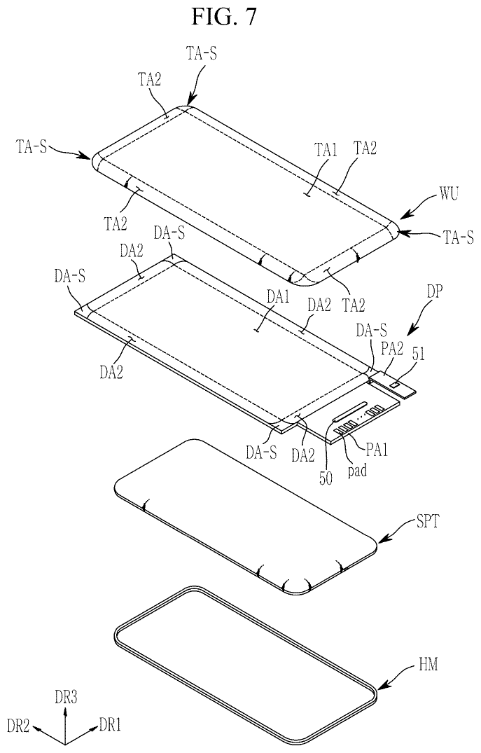

Hereinafter, an overall structure of a bent emissive display device that includes a normal area and a curved bending area as a display area will be described with FIG. 6 and FIG. 7.

FIG. 6 illustrates a schematic perspective view showing a use state of an emissive display device, according to an embodiment, and FIG. 7 illustrates an exploded perspective view of an emissive display device, according to an embodiment.

In an embodiment, the emissive display device 1000, which is a device for displaying a moving image or a still image, may be used as a display screen of various products, such as a television, a laptop computer, a monitor, a billboard, the Internet of things (IOT), etc., as well as portable electronic devices such as a mobile phone, a smart phone, a tablet personal computer, a mobile communication terminal, an electronic notebook, an e-book, a portable multimedia player (PMP), a navigation system, and an ultra-mobile PC (UMPC). In addition, the emissive display device 1000, according to an embodiment, may be used in a wearable device such as a smart watch, a watch phone, a glasses display, or a head-mounted display (HMD). In addition, the emissive display device 1000, according to an embodiment, may be used as an instrument panel of a vehicle, a center information display (CID) provided at a center fascia or dashboard of a vehicle, a room mirror display that replaces a side mirror of a vehicle, or a display provided on a back surface of a front seat of a vehicle. FIG. 6 illustrates an embodiment where the emissive display device 1000 is used as a smart phone for convenience of description.

In addition, the emissive display device 1000, according to an embodiment, may include a display area DA, where the display area DA may be divided into a normal display area DA1 (hereinafter, also referred to as a first display area or main display area) and bending display areas DA2 and DA-S (hereinafter, also referred to as second display areas or auxiliary display areas).

In an embodiment, the normal display area DA1 may be directed parallel to the first direction DR1 and the second direction DR2, and may have a flat display surface, and the bending display areas DA2 and DA-S may be positioned outside the display surface and directed parallel to each of the first direction DR1 and the second direction DR2 and at a bent portion of the display surface, and may have a structure that is bent with a predetermined curvature. The bending display areas DA2 and DA-S may be divided into a first bending display area DA2 (hereinafter also referred to as a second-1 display area or a first auxiliary display area) positioned by bending from a side of the normal display area DA1 and a second bending display area DA-S (hereinafter also referred to as a second-2 display area or a second auxiliary display area) positioned by bending from a corner of the normal display area DA1. A boundary portion BRL may be positioned between the first bending display area DA2 and the second bending display area DA-S, but according to another embodiment, the boundary portion BRL may not be visible to a user.

In an embodiment and referring to FIG. 7, the emissive display device 1000 may include a cover window WU, a display panel DP, a support SPT, and a housing HM.

In an embodiment, the cover window WU may be positioned on a front surface of the display panel DP. In the present embodiment, front (or upper) and back (or lower) surfaces of each member are defined with reference to the third direction DR3. The front and rear surfaces may be disposed opposite to each other in the third direction DR3, and a normal direction of each of the front and rear surfaces may be directed parallel to the third direction DR3. A distance between the front surface and the rear surface in the third direction DR3 may correspond to a thickness of a display panel DP in the third direction DR3.

In an embodiment, the cover window WU may protect the display panel DP from external impacts, etc., and may include a transparent material. For example, the cover window WU may include glass or a transparent synthetic resin. The cover window WU may include transmissive areas TA1, TA2, and TA-S such that an image can be viewed from a front thereof. Herein, the transmissive areas TA1, TA2, and TA-S may be divided into a normal transmissive area TA1 corresponding to the normal display area DA1, a first bending transmissive area TA2 corresponding to the first bending display area DA2, and a second bending transmissive area TA-S corresponding to the second bending display area DA-S. Meanwhile, according to another embodiment, the cover window WU may include the anti-reflection layer ARL as shown in FIG. 3.

In an embodiment, the display panel DP may include the display areas DA1, DA2, and DA-S and peripheral areas PA1 and PA2, and drivers 50 and 51 positioned outside the display areas DA1, DA2, and DA-S.

In an embodiment, a pixel including a light emitting device is positioned in each of the display areas DA1, DA2, and DA-S, and it may be an area in which the pixel operates according to an electrical signal to emit light. In an embodiment, a touch sensor may be positioned above the display areas DA1, DA2, and DA-S so as to sense external input.

The peripheral areas PA1 and PA2 may be positioned in a peripheral area outside of the display areas DA1, DA2, and DA-S.

In an embodiment, a first driver 50 may be positioned in the first peripheral area PA1 to drive the pixels positioned in the display areas DA1, DA2, and DA-S to display images, and the second driver 51 may be positioned in the second peripheral area PA2 to detect an external touch. Specifically, the first driver 50 may be electrically connected to the display areas DA1, DA2, and DA-S to transmit electrical signals to the display areas DA1, DA2, and DA-S. For example, the first driver 50 may provide data signals to pixels arranged in the display areas DA1, DA2, and DA-S.

Additionally, in an embodiment, the emissive display device 1000 may include a pad positioned at an end of the first peripheral area PA1, and may be electrically connected to a printed circuit board (not shown) including a driving chip by the pad. According to another embodiment, a pad portion may also be formed in the second peripheral area PA2 to receive or transmit data from the outside.

In an embodiment, the emissive display device 1000 may sense a user input applied from the outside. The user input may include various types of external inputs, such as a part of a user's body, light, heat, or pressure. In an embodiment, the user input is illustrated as a user hand applied to the front surface. However, the invention is not limited thereto. The user input may be provided in various forms, and in addition, the emissive display device 1000 may sense the user input applied to the side surface or the rear surface of the emissive display device 1000 depending on a structure of the emissive display device 1000.

In an embodiment, the support SPT serves to support the display areas DA1, DA2, and DA-S such that the normal display area DA1 has a flat structure and the bending display areas DA2 and DA-S have a bent structure. The support SPT may be formed of various materials such as glass, plastic, or metal.

In an embodiment, the housing HM may be coupled to the cover window WU to constitute appearance of the emissive display device 1000. The housing HM may be coupled to the cover window WU to provide a predetermined accommodation space. The display panel DP and the support SPT may be accommodated in a predetermined accommodation space provided between the housing HM and the cover window WU.

The housing HM may include a material having relatively high rigidity. For example, the housing HM may include a plurality of frames and/or plates made of glass, plastic, metal, or a combination thereof. The housing HM may stably protect components of the emissive display device 1000 accommodated in an internal space from external impact.

FIG. 8 shows a display panel DP that may be included in the emissive display device 1000, according to an embodiment.

FIG. 8 illustrates a schematic perspective view of a display panel, according to an embodiment.

In an embodiment, the display panel DP shown in FIG. 8 has a structure in which each of the four sides are bent and folded and has a structure in which the display area DA is folded by bending lines BL1, BL2, BL3, and BL4, to be divided into a normal display area DA1 and bending display areas DA21, DA22, DA23, and DA24.

In an embodiment, the normal display area DA1 may have a quadrangular planar shape with the first direction DR1 and the second direction DR2, but the invention is not limited thereto. The normal display area DA1 may have a different polygonal, circular, or oval planar shape. In the normal display area DA1, a corner where the first direction DR1 and the second direction DR2 meet may be rounded to have a predetermined curvature or formed at a right angle. The normal display area DA1 may be formed flat or may include a curved surface.

Each of the bending display areas DA21, DA22, DA23, and DA24 will be separately described as follows.

In an embodiment, the first side bending display area DA21 may extend from a first side of the normal display area DA1. The first side bending display area DA21 may be bent along a first bending line BL1 at the first side of the normal display area DA1 and may have a first curvature. Relative to the normal display area DA1, a bending angle of the first side bending display area DA21 may be approximately 90 degrees or less. The first side of the normal display area DA1 may be a left side of the normal display area DA1.

In an embodiment, a second side bending display area DA22 may extend from a second side of the normal display area DA1. The second side bending display area DA22 may be bent along a second bending line BL2 at the second side of the normal display area DA1 and may have a second curvature. The second curvature may be substantially the same as or different from the first curvature. Relative to the normal display area DA1, a bending angle of the second side bending display area DA22 may be approximately 90 degrees or less. The second side of the normal display area DA1 may be a right side of the normal display area DA1.

In an embodiment, a third side bending display area DA23 may extend from a third side of the normal display area DA1. The third side bending display area DA23 may be bent along a third bending line BL3 at the third side of the normal display area DA1 and may have a third curvature. Relative to the normal display area DA1, a bending angle of the third side bending display area DA23 may be approximately 90 degrees or less. The third side of the normal display area DA1 may be a lower side of the normal display area DA1.

In an embodiment, a fourth side bending display area DA24 may extend from a fourth side of the normal display area DA1. The fourth side bending display area DA24 may be bent along a fourth bending line BL4 at the fourth side of the normal display area DA1 and may have a fourth curvature. The fourth curvature may be substantially the same as or different from the third curvature. Relative to the normal display area DA1, a bending angle of the fourth side bending display area DA24 may be approximately 90 degrees or less. The fourth side of the normal display area DA1 may be an upper side of the normal display area DA1.

Additionally, according to another embodiment, the display panel DP may further include a second bending display area DA-S that is bent at a corner as shown in FIG. 7.

The emissive display device with flexible characteristics has been described, and among them, the structure of the foldable emissive display device has been described in FIG. 5 and the bent emissive display device in which a portion of the display area is bent has been described in FIG. 6. FIG. 5 or FIG. 6 illustrates an example of a flexible emissive display device, so the following embodiments may be applied to various flexible emissive display devices.

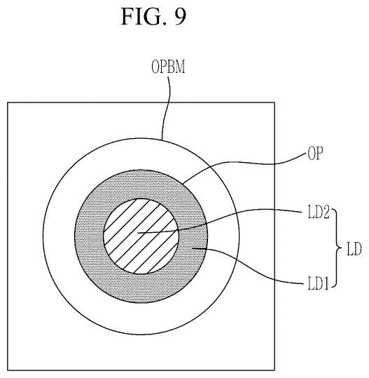

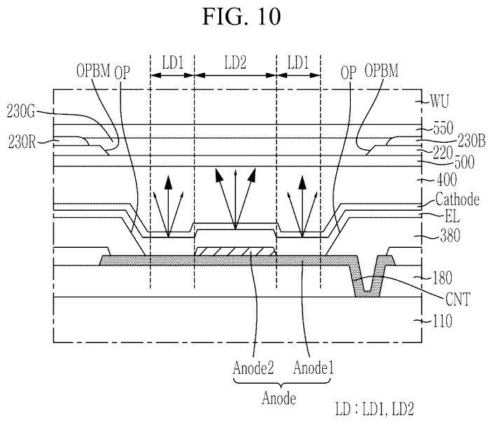

Hereinafter, a structure of a light emitting diode having a step difference, according to an embodiment, will be described through FIGS. 9 and 10, and a planar structure will first be described through FIG. 9.

FIG. 9 illustrates a partial top plan view of an emissive display device, according to an embodiment.

FIG. 9 illustrates a planar structure of one light emitting diode included in an emissive display device, according to an embodiment.

In an embodiment and referring to FIG. 9, an emissive display device includes two light emitting diodes LD1 and LD2 that have different cathode heights and that form a stepped structure. The two light emitting diodes LD1 and LD2 are positioned within an opening OP of a pixel defining layer, and the opening OP of the pixel defining layer (see 380 in FIG. 10) is positioned within a second opening OPBM of a light blocking layer (see 220 in FIG. 10).

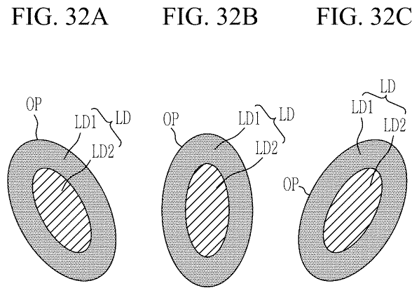

In the embodiment of FIG. 9, the opening OP of the pixel defining layer and the second opening OPBM of the light blocking layer each have a circular shape. According to another embodiment, planar shapes of the opening OP of the pixel defining layer and the second opening OPBM of the light blocking layer may vary, and will be described in FIGS. 32 to 34.

In an embodiment, one light emitting diode LD may be divided into a first light emitting diode LD1 and a second light emitting diode LD2, where the first light emitting diode LD1 and the second light emitting diode LD2 are electrically connected so that anodes of the two light emitting diodes LD1 and LD2 (see Anode in FIG. 10) are connected to each other, and cathodes of the two light emitting diodes LD1 and LD2 (see Cathode in FIG. 10) are connected to each other.

In the embodiment of FIG. 9, the first light emitting diode LD1 has a structure surrounding the second light emitting diode LD2 in a plan view. A planar shape of the first light emitting diode LD1 has a donut shape, and a planar shape of the second light emitting diode LD2 has a circular shape.

The two light emitting diodes LD1 and LD2 are positioned within the opening OP of the pixel defining layer and are also positioned within the second opening OPBM of the light blocking layer in a plan view.

The second light emitting diode LD2 may be formed at a position that overlaps a center of the opening OP of the pixel defining layer and/or a center of the second opening OPBM of the light blocking layer in a plan view, and according to another embodiment, a center of the second light emitting diode LD2 in a plan view may coincide with the center of the opening OP of the pixel defining layer and/or the center of the second opening OPBM of the light blocking layer. Meanwhile, the planar center of the first light emitting diode LD1 may be positioned at a position that overlaps the second light emitting diode LD2 and may coincide with the center of the second light emitting diode LD2.

The first light emitting diode LD1 may be formed to be thinner than the second light emitting diode LD2 (see FIG. 10), and in the two light emitting diodes LD1 and LD2, a height of the cathode relative to the anode (hereinafter referred to as the height of the cathode) is higher in the second light emitting diode LD2. Herein, a thickness of the light emitting diode may be a thickness from a lower surface of the anode to an upper surface of the cathode.

A thickness and a height of the two light emitting diodes LD1 and LD2 will be described in more detail through a cross-sectional structure of FIG. 10.

FIG. 10 illustrates a schematic cross-sectional view of an emissive display device of FIG. 9, according to an embodiment.

According to an embodiment, the emissive display device may display an image by forming a light emitting diode LD on the substrate 110, may include a plurality of sensing electrodes to detect touch, and may include a light blocking layer 220 and a color filter 230.

In addition, according to an embodiment, a polarizer may not be formed on a front surface of the light emitting display panel DP, and instead, the light blocking layer 220 and the color filter 230 may be formed at an upper portion while a pixel defining layer 380 is formed of a black organic material, and even if external light enters an interior, it may be prevented from being reflected by the anode or the like and transmitted to a user.

An emissive display device, according to an embodiment, will be described as follows.

In an embodiment, the substrate 110 may include a material that has rigidity such as glass so as to not bend, or may include a flexible material that can be bent, such as plastic or a polyimide.

In an embodiment, a plurality of thin film transistors are positioned on the substrate 110, but are omitted in FIG. 10, and the organic layer 180 covering the thin film transistors is shown. One pixel is formed with a light emitting diode and a pixel circuit portion including a plurality of transistors and capacitors that transmit light emitting currents to the light emitting diode. In FIG. 10, the pixel circuit portion is not shown, and a structure of the pixel circuit portion may vary, according to an embodiment. In FIG. 10, the organic layer 180 covering the pixel circuit portion is shown first.

In an embodiment, an anode, an intermediate layer EL including a light emitting layer, and a light emitting diode LD including a cathode are positioned on the organic layer 180. A contact hole CNT is positioned in the organic layer 180, and a transistor positioned at a lower portion of the organic layer 180 and the anode of the light emitting diode LD are electrically connected through the contact hole CNT.

In an embodiment, an anode (hereinafter also referred to as a first electrode) includes a first anode Anode1 and a second anode Anode2 positioned on the first anode Anode1 and overlapping a portion of the first anode Anode1. Both the first anode Anode1 and the second anode Anode2 have a conductive charge, so the same voltage or current may be applied thereto.

In an embodiment, the first anode Anode1 may be formed of a single layer including a transparent conductive oxide layer and a metal material, or a multiple layer including these. The transparent conductive oxide film may include an indium tin oxide (ITO), a poly-ITO, an indium zinc oxide (IZO), an indium gallium zinc oxide (IGZO), and an indium tin zinc oxide (ITZO), and the metal material may include silver (Ag), molybdenum (Mo), copper (Cu), gold (Au), and aluminum (Al). In FIG. 10, the first anode Anode1 is shown as if formed as a single layer, but the first anode Anode1, according to an embodiment, may have a double-layer structure, including a first layer formed of a metallic material and a second layer formed of a transparent conductive oxide film. The first anode Anode1 may form a reflective electrode by reflecting all light due to the first layer being formed of a metal material. The following description will focus on an example in which the first anode Anode1 is formed of a double layer.

In an embodiment, the second anode Anode2 may be formed as a transparent electrode containing a transparent conductive material, a transparent conductive oxide film is used as a transparent conductive material, and it may include an indium tin oxide (ITO), a poly-ITO, an indium zinc oxide (IZO), an indium gallium zinc oxide (IGZO), an indium tin zinc oxide (ITZO), etc., and hereinafter, the description will focus on an example formed of the IZO.

The second anode Anode2 may be in direct contact with a portion of the first anode Anode1, and the second anode Anode2 may have a planar structure that is symmetrical with respect to a center of the opening OP of the pixel defining layer. Additionally, according to another embodiment, an edge of the second anode Anode2 may be positioned at a certain horizontal distance from a boundary of the opening OP of the pixel defining layer in a plan view. Herein, the symmetrical planar structure may indicate that two edges of the second anode Anode2 positioned in opposite directions based on the center of the opening OP of the pixel defining layer are positioned at the same distance and may include a case where a distance difference is less than about 10%, considering tolerances.

Referring again to FIG. 9, the second anode Anode2 and the first anode Anode1 may have the same planar shape.

In an embodiment, the second anode Anode2 may be positioned within the opening OP of the pixel defining layer and/or the second opening OPBM of the light blocking layer in a plan view. In addition, the second anode Anode2 may be formed at a position overlapping a center of the first anode Anode1, and the second light emitting diode LD2 may be formed at a position that overlaps a center of the opening OP of the pixel defining layer and/or a center of the second opening OPBM of the light blocking layer in a plan view and, according to another embodiment, a center of the second light emitting diode LD2 in a plan view may coincide with the center of the opening OP of the pixel defining layer and/or the center of the second opening OPBM of the light blocking layer. Moreover, the planar center of the first light emitting diode LD1 may be disposed at a position that overlaps the second light emitting diode LD2, and may coincide with the center of the second light emitting diode LD2.

In an embodiment, the anode may be formed to entirely have a structure with steps due to the second anode Anode2, and in this case, the first anode Anode1 may be formed to have a structure without steps.

In an embodiment, the pixel defining layer 380 is positioned on the organic layer 180 and the anode, and the pixel defining layer 380 has an opening (OP; hereinafter also referred to as a first opening), and the opening OP of the pixel defining layer 380 overlaps a portion of the anode. Referring to FIG. 10, the second anode Anode2 may overlap the opening OP and may not overlap the pixel defining layer 380, and the first anode Anode1 may have a structure that overlaps the pixel defining layer 380 and the opening OP of the pixel defining layer 380.

In an embodiment, the pixel defining layer 380 may be formed of a negative-type black organic material. The black organic material may include a light blocking material, and the light blocking material may include carbon black, carbon nanotubes, resin or paste containing black dye, metal particles such as nickel, aluminum, molybdenum and their alloys, metal oxide particles (e.g., chromium nitride), etc. The pixel defining layer 380 may contain a light blocking material, may be black in color, and may have characteristics of absorbing/blocking light rather than reflecting it. Because a negative-type organic material is used, it may have a property of removing a portion covered by a mask.

In an embodiment, t spacer (see 385 in FIG. 36) may be positioned on the pixel defining layer 380. The spacer includes a first portion (see 385-1 in FIG. 36) positioned in a high and narrow region and a second portion (see 385-2 in FIG. 36) positioned in a low and wide region. Herein, the first portion may serve to secure rigidity against pressing pressure by enhancing scratch strength. The second portion may serve to assist contact between the pixel defining layer 380 and the upper functional layer. The first portion and the second portion of the spacer may be formed of the same material, and may be formed of a positive type photosensitive organic material—for example, photosensitive polyimide (PSPI). Because it has a positive characteristic, portions not covered by the mask may be removed. The spacer may be transparent so that light may be transmitted and/or reflected.

In an embodiment, the pixel defining layer 380 may be formed as a negative type, the spacer may be formed as a positive type and, according to another embodiment, they may include homogeneous materials.

In an embodiment, at least a portion of an upper surface of the pixel defining layer 380 is covered by the spacer, and an edge of a second portion of the spacer has a structure that is spaced apart from an edge of the pixel defining layer 380, so that a portion of the pixel defining layer 380 is not covered by the spacer. The second portion of the spacer may cover even the upper surface of the pixel defining layer 380 where the first portion of the spacer is not positioned, thereby strengthening an adhesion characteristic between the pixel defining layer 380 and the functional layer. In an embodiment, the spacer may be positioned in a region that overlaps the light blocking layer 220, which will be described later, in a plan view so that when viewed from the front surface of the display panel DP, the spacer may be obscured by the light blocking layer 220.

In an embodiment, the spacer may increase the scratch strength on the light emitting display panel DP to reduce incidence of defects due to pressing pressure and, according to another embodiment, adhesion with the functional layer positioned at an upper portion of the spacer may be increased to prevent moisture and air from being injected from the outside. In addition, high adhesive strength has an advantage of eliminating a problem of poor adhesion between layers when the light emitting display panel DP has a flexible characteristic and is folded and unfolded.

In an embodiment, an intermediate layer EL including a light emitting layer is positioned on the anode exposed by the opening OP of the pixel defining layer 380.

In an embodiment, the light emitting layer (see EML in FIG. 36) may be formed of an organic light emitting material, may be positioned only within the opening OP of the pixel defining layer 380, and is separated from the adjacent light emitting layer by the pixel defining layer 380. Adjacent light emitting layers may display different colors. Meanwhile, according to another embodiment, each light emitting layer may display light of the same color due to the color filters 230R, 230G, and 230B positioned at an upper portion. According to another embodiment, the light emitting layer may have a structure in which a plurality of light emitting layers are stacked (also called a tandem structure).

In an embodiment, the intermediate layer EL may further include a functional layer (see FL in FIG. 36) in addition to the light emitting layer, where the functional layer may include at least one of an electron injection layer, an electron transport layer, a hole transport layer, or a hole injection layer. The functional layer may be positioned above and below the light emitting layer. That is, the hole injection layer, the hole transport layer, the light emitting layer, the electron transport layer, the electron injection layer, and the cathode may be sequentially positioned on the anode, so in the functional layer, the hole injection layer and the hole transport layer may be disposed below the light emitting layer, and the electron transport layer and the electron injection layer may be disposed at an upper portion of the light emitting layer.

In an embodiment, the intermediate layer EL or a functional layer in the intermediate layer EL may also be positioned on the spacer 385 and the exposed pixel defining layer 380, and may be disposed on an entire surface of the light emitting display panel DP or may be formed on some areas—for example, all areas excluding a light transmitting area of the second component area EA2.

In an embodiment, the intermediate layer EL may be disposed along a step of the anode caused by the second anode Anode2, and the intermediate layer EL disposed on the second anode Anode2 may have a higher upper surface than the intermediate layer EL disposed on the first anode Anode1.

In an embodiment, a cathode (hereinafter also referred to as a second electrode) is positioned on the intermediate layer EL. The cathode may be a translucent electrode and may be formed as a metal thin film with a small work function containing lithium (Li), calcium (Ca), lithium/calcium fluoride (LiF/Ca), lithium/aluminum fluoride (LiF/Al), aluminum (Al), silver (Ag), magnesium (Mg) and a compound thereof. According to another embodiment, for the cathode, a transparent conductive oxide (TCO) film, made of an indium tin oxide (ITO), an indium zinc oxide (IZO), a zinc oxide (ZnO), or an indium oxide (In2O3), may be further positioned on the metal thin film. The cathode may be formed integrally over the entire surface of the light emitting display panel DP.

In an embodiment, the cathode is positioned on the intermediate layer EL, and the cathode is formed in a structure with a step according to a step of the intermediate layer EL. Specifically, the cathode may have a step in a region overlapping the opening OP of the pixel defining layer. A portion of the cathode that overlaps the second anode Anode2 may have a higher upper surface than a portion that overlaps the first anode Anode1.

In an embodiment, the first light emitting diode LD1 may be configured to include a portion of the first anode Anode1 that does not overlap the second anode Anode2, a cathode facing a portion of the first anode Anode1, and an intermediate layer EL positioned between the portion of the first anode Anode1 and the cathode which is facing the portion of the first anode Anode1.

In an embodiment, the second light emitting diode LD2 may be configured to include a second anode Anode2, a cathode facing the second anode Anode2, and an intermediate EL positioned between the second anode Anode2 and the cathode facing the second anode Anode2 and may also include a portion of the first anode Anode1 that overlaps the second anode Anode2.

In an embodiment, the second anode Anode2 may be positioned on the first anode Anode1, so an anode thickness of the second light emitting diode LD2 may be greater, and a height of the cathode of the second light emitting diode LD2 may also be greater. A portion of the first anode Anode1 covered by the pixel defining layer 380 may not be included in the light emitting diode LD.

In an embodiment, the cathode has a translucent characteristic and serves as a translucent electrode that transmits some light and reflects the remaining light. Meanwhile, since the anode Anode serves as a reflective electrode, a phenomenon in which light resonates (micro-cavity) occurs between the anode and the cathode.

Specifically, some of the light emitted from the light emitting layer and incident on the cathode is transmitted, but the remaining light is reflected and transmitted to the anode. All the light is reflected from the anode, so it is transmitted back to the cathode, and some of it is reflected again. During this optical cycle, lights interfere with each other. If a thickness of the light emitting layer and/or the intermediate layer is adjusted such that constructive interference occurs during the interference phenomenon, light with a specific frequency (color of light) is reinforced and provided to a user's eyes. This resonance method has the advantage of improving optical efficiency.

In an embodiment, the second anode Anode2 is a transparent electrode made of a transparent conductive material, so it transmits light without reflecting it, and thus a resonance structure of the second light emitting diode LD2 and a resonance structure of the first light emitting diode LD1 both occur between the cathode and the first anode Anode1. A thickness of the resonance structure of the first light emitting diode LD1—i.e., a thickness between the cathode and the first anode Anode1 of the first light emitting diode LD1—is different from the thickness of the resonance structure of the second light emitting diode LD2—i.e., the thickness between the cathode and the first anode Anode1 of the first light emitting diode LD1, and thus a wavelength range in which constructive interference occurs may be different due to resonance between the two light emitting diodes LD1 and LD2. Such a structure includes two or more resonance structures, which is also called a multi-resonance structure.

In an embodiment and referring to FIG. 10, the encapsulation layer 400 is positioned on the cathode. The encapsulation layer 400 may include at least one inorganic layer and at least one organic layer and may have a triple-layer structure in which a lower inorganic encapsulation layer, an organic encapsulation layer, and an upper inorganic encapsulation layer are sequentially disposed. A first end of the encapsulation layer 400 may have a structure in which the lower inorganic encapsulation layer and the upper inorganic encapsulation layer are in contact, which may serve to protect the light emitting layer formed of organic materials from moisture or oxygen that may enter from the outside. According to an embodiment, the encapsulation layer 400 may include a structure in which an inorganic layer and an organic layer are further sequentially stacked.

In an embodiment, a touch sensing layer 500 capable of detecting touch may be positioned on the encapsulation layer 400, where the touch sensing layer 500 may include a sensing insulating layer (see 501, 510, and 511 in FIG. 36) and a plurality of sensing electrodes (see 540 and 541 in FIG. 36).

In an embodiment, a light blocking layer 220 and color filters 230R, 230G, and 230B are positioned on the touch sensing layer 500.

In an embodiment, the light blocking layer 220 may be positioned to overlap the pixel defining layer 380 in a plan view and may be positioned not to overlap the anode in a plan view. This is to ensure that the anode and the light emitting layer capable of displaying an image are not obscured by the light blocking layer 220.

The light blocking layer 220 may also have a second opening OPBM (hereinafter also referred to as the second opening), where the area of the second opening OPBM of the light blocking layer 220 may be formed to be larger than that of the opening OP of the pixel defining layer 380, and where the light blocking layer 220 may also be positioned within the second opening OPBM of the opening OP of the pixel defining layer 380 in a plan view.

In an embodiment, the color filters 230R, 230G, and 230B are positioned on the light blocking layer 220 and include a red color filter 230R for transmitting red light, a green color filter 230G for transmitting green light, and a blue color filter 230B for transmitting blue light. Each of the color filters 230R, 230G, and 230B may be positioned to overlap the anode of the light emitting diode in a plan view, and the second opening OPBM of the light blocking layer 220 may be filled with a single color of color filters 230R, 230G, and 230B. Some of the color filters 230R, 230G, and 230B may also be positioned on an upper surface of the light blocking layer 220. Light emitted from a light emitting layer of a light emitting diode may change to a corresponding color as it passes through a color filter, so all light emitted from the light emitting layer may have the same color. However, the light emitting layer may emit light of different colors, and a displayed color may be strengthened by passing through a color filter of the same color.

In an embodiment, the light blocking layer 220 may be disposed between each of the color filters 230R, 230G, and 230B. According to an embodiment, the color filters 230R, 230G, and 230B may be replaced with a color conversion layer or may further include a color conversion layer. The color conversion layer may include a quantum dot.

In an embodiment, the planarization layer 550 covering color filters 230R, 230G, and 230B is disposed on the color filters 230R, 230G, and 230B. The planarization layer 550 may be used to planarize the upper surface of the light emitting display panel and may be a transparent organic insulating layer containing one or more materials of polyimide, polyamide, acrylic resin, benzocyclobutene, and phenol resin.

According to an embodiment, a low-refractive layer and an additional planarization layer may be further positioned on the planarization layer 550 to improve frontal visibility and light output efficiency of the display panel. Light may be refracted and emitted toward the front by a low-refractive layer and an additional planarization layer with a high-refractive characteristics. According to another embodiment, the planarization layer 550 may be omitted and a low-refractive layer and an additional planarization layer may be positioned directly on the color filter 230.

In an embodiment, the cover window WU may be positioned at an upper portion of the planarization layer 550 and may further include an additional optical film and, according to another embodiment, may have a structure as shown in FIG. 3. According to another embodiment, cover window WU may not include a polarizer or may include a polarizer.

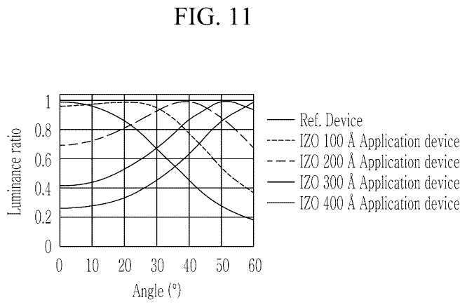

An effect caused by the second anode Anode2 formed of a transparent conductive material as shown in FIGS. 9 and 10 will be described in detail through FIGS. 11 to 20, and in the following, results of an experiment using an example including the second anode Anode2 formed of IZO are shown.

FIG. 11 to FIG. 20 illustrate a graph for describing an effect, according to the embodiment of FIG. 9.

First, FIG. 11 shows the seconds of a second light emitting diode according to an angle caused by varying the thickness of the second anode. Herein, IZO represents the second anode, and “Ref. device” represents a structure without the second anode—i.e., a luminance ratio according to an angle of a first light emitting diode.

In an embodiment and referring to FIG. 11, it may be seen that the luminance ratio of the second light emitting diode changes according to the angle depending on the thickness of the second anode.

In FIG. 11, it may be seen that the luminance ratio of the “Ref. device”—i.e., the first light emitting diode—decreases toward the side relative to the front (0 degrees).

In FIG. 11, when the thickness of the second anode is about 100 Å, the luminance ratio of the second light emitting diode is also lower from the side than from the front (0 degrees). However, in an embodiment in which the thickness of the second anode is about 200 Å or more, it may be seen that the luminance ratio at the front (0 degrees) is low and the luminance ratio at the side is high. In FIG. 11, in the embodiment where the thickness of the second anode is about 100 Å, the luminance ratio at the front (0 degrees) is also high, exceeding about 0.9, but it has a maximum luminance ratio around 20 degrees at the side, and after that, the luminance ratio decreases toward the side. In an embodiment in which the thickness of the second anode is about 200 Å, the luminance ratio at the front (about 0 degrees) has a low value of about 0.7, with a maximum luminance ratio around 40 degrees at the side, and thereafter, the luminance ratio decreases toward the side. In an embodiment in which the thickness of the second anode is about 300 Å, the luminance ratio at the front (about 0 degrees) has a low value of about 0.4, with a maximum luminance ratio around 50 degrees at the side, and thereafter, the luminance ratio decreases toward the side. In the embodiment where the thickness of the second anode is about 400 Å, it may be seen that the luminance ratio at the front (about 0 degrees) has a low value of about 0.3, and the luminance ratio increases toward the side.

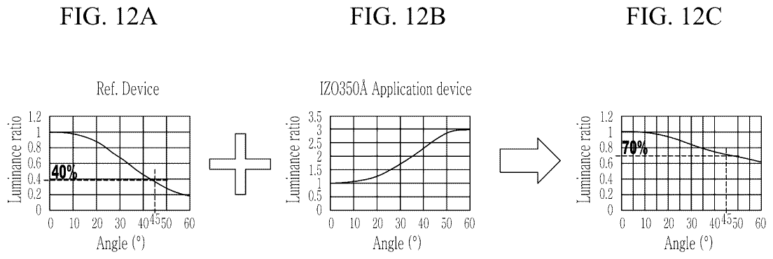

Considering the luminance ratio according to the angle of the second light emitting diode as shown in FIG. 11 and the luminance ratio according to the angle of the first light emitting diode shown as “Ref. device,” the light emitting diodes according to the embodiments of FIGS. 9 and 10 have a combined luminance ratio as shown in FIG. 12.

FIG. 12A shows a luminance ratio according to an angle of the “Ref. device” of FIG. 11—i.e., the first light emitting diode—and FIG. 12B shows a luminance ratio according to an angle of a second light emitting diode with the second anode having a thickness of about 350 Å. FIG. 12C shows a sum of the luminance ratios according to the angle of FIGS. 12A and 12B, and shows a luminance ratio according to an angle of all light emitting diodes including the first and second light emitting diodes as in the embodiments of FIGS. 9 and 10.

In an embodiment and referring to FIG. 12A, it may be seen that the luminance ratio of the first light emitting diode decreases toward the side relative to the front (about 0 degrees), and referring to FIG. 12B, the second light emitting diode has a low luminance ratio at the front (about 0 degrees) and a high luminance ratio toward the side, so when they are combined, as shown in FIG. 12C, the luminance ratio from the side is lower than that from the front, but it may have a luminance ratio of about 0.7 (about 70%) at about 45 degrees from the side. Particularly, referring to FIG. 12A, it may be seen that relative to the luminance ratio of about 0.4 (about 40%) at a side angle of about 45 degrees when including only the first light emitting diode, as in the embodiments of FIGS. 9 and 10, the luminance ratio at the side can be improved by additionally forming a second anode to include a second light emitting diode.

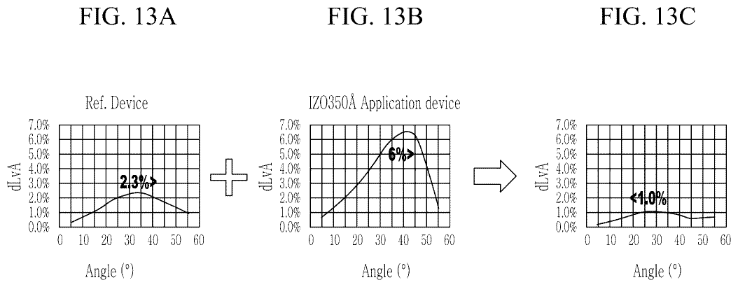

Meanwhile, in FIG. 13, a rate of change (dLvA) of luminance according to angle is shown.

In an embodiment, FIG. 13A shows the rate of change (dLvA) of luminance according to an angle of the “Ref. device,” i.e., a first light emitting diode, FIG. 13B shows the rate of change (dLvA) of luminance according to an angle of the second light emitting diode in which the second anode is formed with a thickness of about 350 Å, and FIG. 13C shows a sum of the rate of change (dLvA) of luminance according to the angle of FIGS. 13A and 13B, and shows the rate of change (dLvA) of luminance according to the angle of all light emitting diodes.

In an embodiment and referring to FIG. 13A, it may be seen that the rate of change (dLvA) of luminance according to the angle of the first light emitting diode has a greatest value (about 2.3%) around about 35 degrees, and the rate of change decreases toward both sides. Referring to FIG. 13B, it may be seen that the rate of change (dLvA) of luminance according to the angle of the second light emitting diode is relatively larger than the rate of change (dLvA) of luminance according to the angle of the first light emitting diode, has a maximum value exceeding about 6% around about 40 degrees, and the rate of change decreases relatively significantly toward both sides. FIG. 13C shows a graph obtained by combining the rate of change (dLvA) of luminance according to the angle as shown in FIG. 13A and FIG. 13B, and is the rate of change (dLvA) of luminance according to the angle of all light emitting diodes. Referring to FIGS. 13A, 13B, and 13C, it may be seen that the rate of change (dLvA) of luminance according to the angle of all light emitting diodes has a lower change rate than the rate of change (dLvA) of luminance according to the angle of each of the first and second light emitting diodes, and has a rate of change value of less than about 1.0% as its maximum value. Accordingly, referring to FIG. 13, all the light emitting diodes as shown in FIGS. 9 and 10 may also reduce the rate of change (dLvA) of luminance according to the angle by additionally forming a second anode to form a second light emitting diode, and images of constant quality may be displayed without the display quality changing significantly according to the angle.

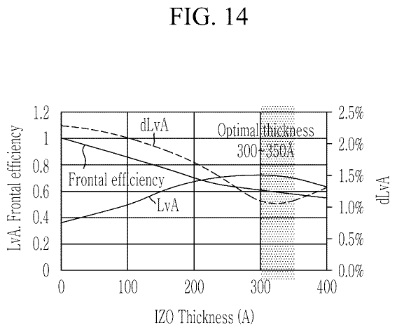

Hereinafter, a luminance ratio (LvA) according to the angle according to the thickness of the second anode, the rate of change (dLvA) of luminance according to the angle, and the frontal efficiency will be described through FIG. 14.

According to an embodiment, in FIG. 14, when the thickness of IZO is about 0, the second anode is not formed, so it corresponds to the previous “Ref. device” and it shows a case where only the first light emitting diode is formed.

According to an embodiment, in FIG. 14, it may be seen that the front-side efficiency decreases as the thickness of the IZO increases, which shows that as the thickness of the second anode increases, the light emitted to the side increases and the luminance at the front decreases.

According to an embodiment, in FIG. 14, it may be seen that the luminance ratio (LvA) according to an angle is the luminance ratio at about 45 degrees from the side, which increases as the thickness of the IZO increases, and it has a maximum angle-dependent luminance ratio (LvA) between about 300 Å and about 350 Å, and as it becomes thicker than that, the luminance ratio also decreases.

According to an embodiment, in FIG. 14, it may be seen that the rate of change (dLvA) of luminance according to angle is also the rate of change of luminance from the side, and as the thickness of the IZO increases, it gradually decreases, has a minimum value above about 300 Å and below about 350 Å, and then increases again.

Accordingly, when the second anode has a thickness of about 300 Å or more and about 350 Å or less, the luminance ratio (LvA) according to the angle is maximized, and the rate of change (dLvA) of luminance according to the angle is minimized, so that the display quality is most improved. This is only the optimal thickness of the optimized second anode, so the thickness of the second anode is not limited thereto. That is, referring to FIG. 11, even when the thickness of the second anode is about 100 Å, the luminance ratio at around 20 degrees is higher than at the front, so it is effective in sending light to the side. Additionally, in FIG. 11, even when the second anode has a thickness of about 400 Å, a front luminance ratio may be low and the luminance ratio may increase toward the side, so the second anode having a thickness exceeding about 400 Å may be expected to have similar luminance ratio characteristics. In addition, the second anode may be formed to be about 50 Å or more and about 500 Å or less.

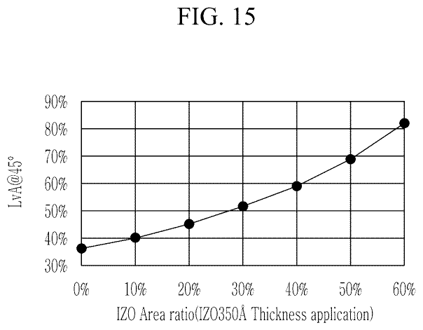

Hereinafter, characteristics according to an area ratio of a second anode will be described through FIGS. 15 to 17, according to an embodiment. Here, the area ratio of the second anode is an area ratio of the second anode to an area of an opening of a pixel defining layer where the second anode is formed in a plan view.

First, FIG. 15 shows how a luminance ratio (LvA) according to an angle at about 45 degrees at the side changes depending on an area of the second anode. Here, the second anode is formed of IZO of about 350 Å.

In FIG. 15, an area ratio of about 0 corresponds to a “Ref. device” in which the second anode is not formed and only the first light emitting diode is formed, and in the case of “Ref. device,” the luminance ratio at about 45 degrees at the side is less than about 40%. However, it may be seen that the luminance ratio at about 45 degrees at the side increases as the second anode is formed and an area thereof increases.

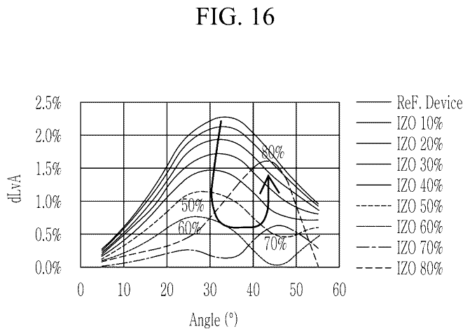

In FIG. 16, the rate of change (dLvA) of luminance according to an angle is shown for various areas of the second anode. Here, the thickness of the second anode is about 350 Å.

According to an embodiment and referring to FIG. 16, it may be seen that as the area ratio of the second anode increases, the rate of change (dLvA) of luminance decreases as a whole, and when the area ratio reaches about 80%, the rate of change (dLvA) of luminance increases again. In FIG. 16, an arrow indicates a line connecting maximum values of the rate of change (dLvA) of luminance at each area ratio, and the area ratio increases in a direction of the arrow.

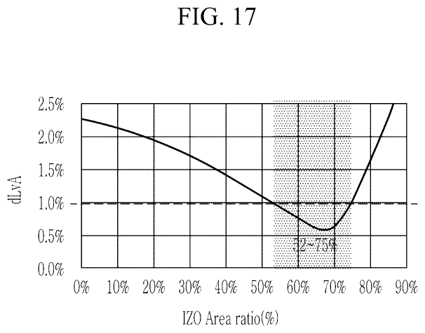

FIG. 17 illustrates a graph showing the rate of change (dLvA) of luminance with respect to an area ratio, and in this case, the thickness of the second anode is about 350 Å.

In an embodiment and referring to FIG. 17, when the area ratio is about 67%, the rate of change (dLvA) of luminance has a minimum value of about 0.6%, and an area ratio with a rate of change (dLvA) of luminance of about 1.0% or less is about 52% or more and less than about 75%. The area ratio in FIG. 17 is an area corresponding to a value of a specific rate of change (dLvA) of luminance, so the second anode may be formed with an area ratio other than this, the rate of change (dLvA) of luminance may decrease as the area ratio increases compared to a case where the area ratio in FIG. 17 is about 0%, and it has a sufficiently low rate of change (dLvA) of luminance of up to about 75%, and thus, according to another embodiment, the area ratio of the second anode may have a value of about 5% or more and about 75% or less.

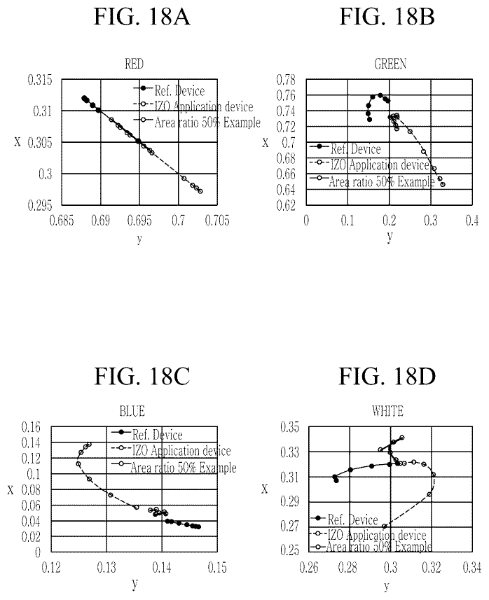

Hereinafter, characteristics of color coordinates will be described in detail with reference to FIG. 18 to FIG. 20, according to an embodiment.

First, FIG. 18 shows the characteristics of the color coordinates of a light emitting diode for each color separately.

FIG. 18A, FIG. 18B, and FIG. 18C show color coordinate characteristics that change when the angle is changed for each of the red, green, and blue light emitting diodes, respectively, and FIG. 18D shows color coordinate characteristics of the white color obtained by combining these characteristics. In addition, in FIG. 18, “Ref. device” includes only a first light emitting diode, an IZO application device includes only the second light emitting diode, and an example with an area ratio of about 50% represents an example in which area ratios of the first light emitting diode and the second light emitting diode are each about 50%.

Specifically, referring to FIG. 18A, red is positioned on a diagonal straight line in the color coordinates, “Ref. device” is positioned on the upper left, and the IZO application device is positioned on the lower right. Meanwhile, the about 50% area ratio example is positioned between the two and has a portion that overlaps some “Ref. devices” and the IZO application device.

Characteristics of green will be described through FIG. 18B in which “Ref. device” is positioned on a curve, the IZO application device is positioned on a line close to a straight line, and they are separated from each other. “Ref. device” is positioned at the upper left side, and the IZO application device is positioned at the lower right side. Meanwhile, the about 50% area ratio example is positioned on a bent curve between the two. The about 50% area ratio example may partially overlap the IZO application device. Herein, the area ratio is the same as that of the second anode described above and is an area ratio of the second anode to an area of an opening of a pixel defining layer where the second anode is formed in a plan view.

Characteristics of blue will be described through FIG. 18C in which “Ref. device” is positioned on a line close to a straight line, the IZO application device is positioned on a curve, and they are separated from each other. “Ref. device” is positioned at the lower right side, and the IZO application device is positioned at the upper left side. Meanwhile, the about 50% area ratio example is positioned in a portion between the two and may not overlap “Ref. device” and the IZO application device.

Such color coordinate characteristics of white, which is obtained by combining the color coordinate characteristics of each color, may be as shown in FIG. 18D. Referring to FIG. 18D, “Ref. device” is positioned on a line close to a straight line, the IZO application device is positioned on a curve. “Ref. device” is positioned at a left side, and the IZO application device is positioned at a right side. Meanwhile, the about 50% area ratio example extends upward from a region between the two and is positioned on a curved line and may overlap “Ref. device” and the IZO application device.

Referring to FIG. 18D, when an angle of the “Ref. device” increases, the luminance decreases as the color coordinates move toward a short wavelength, but as an angle of the IZO application device increases, the luminance increases as the color coordinates move toward the short wavelength. In addition, compared to the “Ref. device,” the IZO application device is positioned in a relatively long wavelength region, so in an example obtained by combining the two characteristics, the color coordinates are positioned in an intermediate region.

In this way and according to an embodiment, merging different characteristics according to an increase in angle may have the advantage of mitigating a change in luminance.

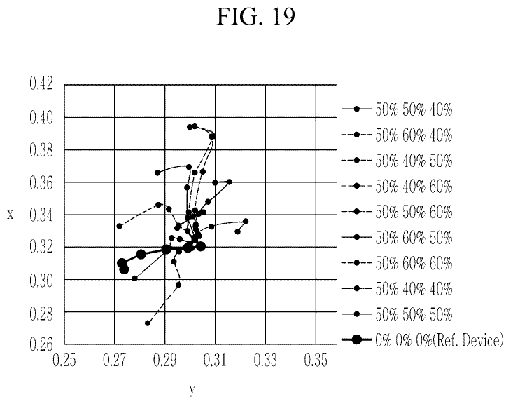

Simulating such color coordinate characteristics while providing various area ratios for each color is shown in FIG. 19, according to an embodiment.

In FIG. 19, area ratios of red, green, and blue are shown in order. A case where the area ratio is about 0 for all colors is a configuration without the second anode, so it corresponds to “Ref. device.”

In an embodiment and referring to FIG. 19, various area ratios are being simulated, and it may be seen that an example in which an area ratio for each color is relatively constant at about 50% has the least change in color coordinates, resulting in less change in color depending on the angle. In other words, if the area ratios of red, green, and blue are different, color perception provided by each color changes, and particularly, a color perception from the side changes more significantly, so it may be preferable in terms of color perception if the area ratio of each color is the same or at an equivalent level (about 0.9 times to about 1.1 times).

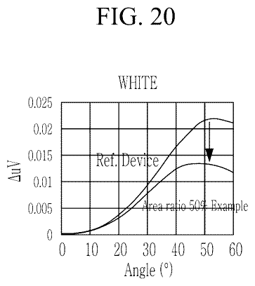

Additionally, FIG. 20 shows a color coordinate change rate (ΔuV) according to an angle for white, which is a combination of three colors. In FIG. 20, only “Ref. device” and about 50% area ratio example are shown. Compared to “Ref. device,” the about 50% area ratio example has a low color coordinate change rate (ΔuV) depending on the angle, so it can have the advantage of providing a relatively constant color at the side compared to the front (0 degrees). In addition, considering that white is a combination of red, green, and blue, it may be seen that the color coordinate change rate (ΔuV) according to an angle is also decreased for each of red, green, and blue.

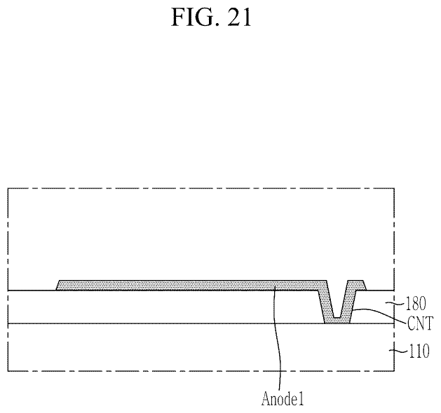

Hereinafter, a manufacturing method of the embodiment of FIGS. 9 and 10 will be described referring to FIGS. 21 through 24.

FIG. 21 to FIG. 24 illustrate cross-sectional views depending on a manufacturing sequence of parts of an emissive display device, according to the embodiment of FIG. 9.

In FIGS. 21 to 24, a space between the organic layer 180 and the substrate 110 is omitted as in FIG. 10.

In an embodiment and referring to FIG. 21, the first anode Anode1 is formed on the organic layer 180 on which the contact hole CNT is formed.

The first anode Anode1 may be completed by stacking the conductive material for the first anode Anode1 and then patterning it. Herein, the conductive material for the first anode Anode1 may include a transparent conductive oxide film and/or a metal material, and the transparent conductive oxide film may include an indium tin oxide (ITO), a poly-ITO, an indium zinc oxide (IZO), an indium gallium zinc oxide (IGZO), and an indium tin zinc oxide (ITZO), and the metal material may include silver (Ag), molybdenum (Mo), copper (Cu), gold (Au), and aluminum (Al).

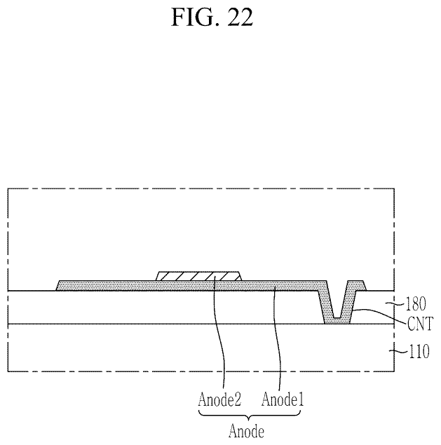

In an embodiment and referring to FIG. 22, after the first anode Anode1 is completed, a transparent conductive material for the second anode Anode2 may be stacked and patterned thereon to complete the second anode Anode2. Herein, the transparent conductive material for the second anode may include a transparent conductive oxide film, and the transparent conductive oxide film may include an indium tin oxide (ITO), a poly-ITO, an indium zinc oxide (IZO), an indium gallium zinc oxide (IGZO), an indium tin zinc oxide (ITZO), etc.

Shapes, sizes, and positions of the first anode Anode1 and the second anode Anode2 may be determined according to a subsequent process, an area ratio, etc., and a thickness of the second anode Anode2 may also be determined by considering a luminance ratio.

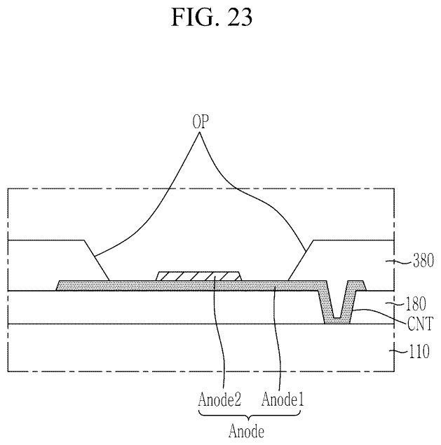

In an embodiment and referring to FIG. 23, after the first anode Anode1 and the second anode Anode2 are completed, a pixel defining layer 380 is formed to have an opening OP that overlaps the first anode Anode1 and the second anode Anode2. Here, the pixel defining layer 380 may be formed of a negative-type black organic material. The black organic material may include a light blocking material, and the light blocking material may include carbon black, carbon nanotubes, resin or paste containing black dye, metal particles such as nickel, aluminum, molybdenum and their alloys, metal oxide particles (e.g., chromium nitride), etc., and the opening OP may be formed using a part covered by a mask.

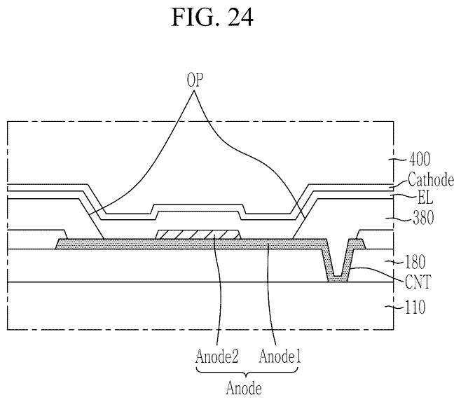

In an embodiment and referring to FIG. 24, an intermediate layer EL and a cathode are sequentially positioned on the pixel defining layer 380 and the anode exposed through the opening OP formed in the pixel defining layer 380. Here, the intermediate layer EL may include a light emitting layer (see EML in FIG. 36), where the light emitting layer may be positioned only within the opening OP of the pixel defining layer 380. The intermediate layer EL may further include a functional layer (see FL in FIG. 36) in addition to the light emitting layer, where the functional layer FL may include at least one of an electron injection layer, an electron transport layer, a hole transport layer, or a hole injection layer, positioned above and below the light emitting layer. According to another embodiment, the light emitting layer included in the intermediate layer EL may have a structure in which a plurality of light emitting layers are stacked (also called a tandem structure).

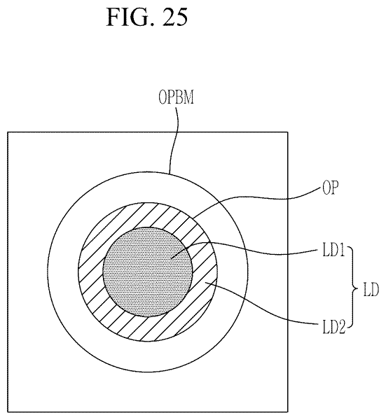

In the above, a manufacturing method of a portion of the emissive display device, according to the embodiment of FIG. 9, has been described through FIGS. 21 to 24. Hereinafter, various embodiments that are different from the embodiment of FIGS. 9 and 10 will be described through FIGS. 25 to 34.

FIG. 25 to FIG. 28 illustrate embodiments in which the second anode Anode2 is not positioned in a center of the opening OP of the pixel defining layer. FIG. 25 to FIG. 28 show embodiments in which a portion of the second anode Anode2 is positioned outside the opening OP of the pixel defining layer and overlaps the pixel defining layer, and a portion of the first anode Anode1 is not covered by the second anode Anode2.

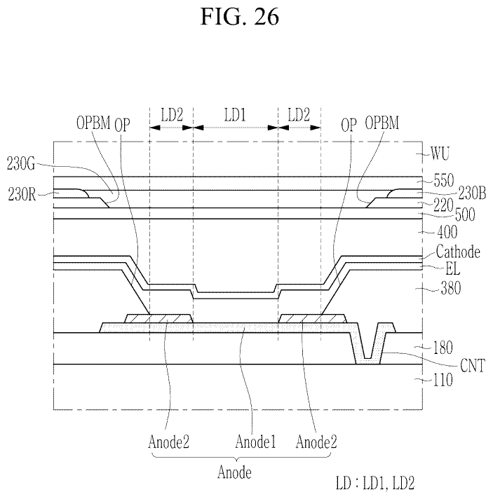

First, an embodiment of FIG. 25 and FIG. 26 will be described.

FIG. 25 illustrates a partial top plan view of an emissive display device, according to another embodiment, and FIG. 26 illustrates a schematic cross-sectional view of the emissive display device of FIG. 25, according to an embodiment.

In the embodiment of FIG. 25 and FIG. 26, unlike in the embodiment of FIGS. 9 and 10, the second light emitting diode LD2 corresponding to the first anode Anode1 and the second anode Anode2 is positioned nearby, and the first light emitting diode LD1, which includes only the first anode Anode1, is positioned in the center.

In an embodiment and referring to FIG. 26, a portion of the second anode Anode2 overlaps the opening OP of the pixel defining layer 380, and a remaining portion of the second anode Anode2 overlaps the pixel defining layer 380 and is covered with the pixel defining layer 380.

In an embodiment, the cathode has a step in a region overlapping the opening OP of the pixel defining layer 380, and has a low height at the center of the opening OP of the pixel defining layer 380 in FIG. 26.

The remaining portion of the embodiment of FIGS. 25 and 26 may be the same as those described in FIGS. 9 and 10, where the embodiment of FIGS. 25 and 26 may also have a multi-resonance structure in which resonance structures of the first light emitting diode LD1 and the second light emitting diode LD2 have different thicknesses, and an effect of the multi-resonance structure described in FIGS. 11 to 20 may be the same or similar.

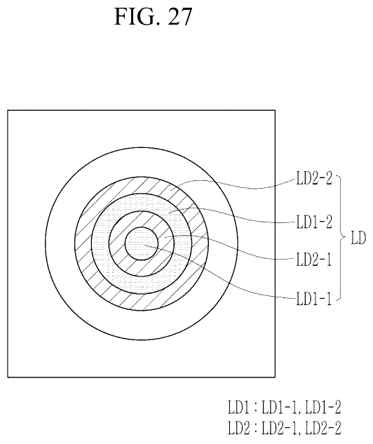

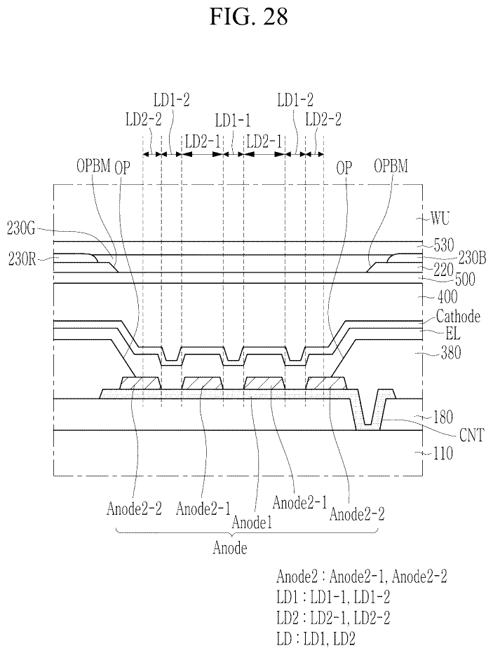

In the embodiments of FIG. 9 and FIG. 25, there is one boundary dividing the first and second light emitting diodes LD1 and LD2 and, according to another embodiment, the first light emitting diode LD1 and the second light emitting diode LD2 may be distinguished based on a plurality of boundaries. An embodiment having this structure will be described through FIGS. 27 and 28.

FIG. 27 illustrates a partial top plan view of an emissive display device, according to another embodiment, and FIG. 28 illustrates a schematic cross-sectional view of the emissive display device of FIG. 27, according to an embodiment.

The embodiment of FIG. 27 and FIG. 28 includes two or more second anodes Anode2-1 and Anode2-2 that are separated from each other.

The embodiments of FIG. 27 and FIG. 28 have a structure in which a first-1 light emitting diode LD1-1 with the first anode Anode1 is positioned in the center, a second-1 light emitting diode LD2-1 corresponding to the first anode Anode1 and the second-1 anode Anode2-1 is positioned around the first-1 light emitting diode LD1-1, the first-2 light emitting diode LD1-2, in which the first anode Anode1 is positioned, is positioned around the first-1 light emitting diode LD1-1, and a second-2 light emitting diode LD2-1 corresponding to the first anode Anode1 and the second-2 anode Anode2-2 is positioned around the first-1 light emitting diode LD1-1. Herein, the anode includes the first anode Anode1 and the second anode Anode2, and the second anode Anode2 includes the second-1 anode Anode2-1 and the second-2 anode Anode2-2. In addition, the light emitting diode LD includes the first light emitting diode LD1 and the second light emitting diode LD2, the first light emitting diode LD1 includes the first-1 light emitting diode LD1-1 and the first-2 light emitting diode LD1-2, and the second light emitting diode LD2 includes the second-1 light emitting diode LD2-1 and the second-2 light emitting diode LD2-2.

Referring to FIG. 28, a portion of the second-2 anode Anode2-2 overlaps the opening OP of the pixel defining layer 380, and a remaining portion of the second-2 anode Anode2-2 overlaps the pixel defining layer 380 and is covered with the pixel defining layer 380. Meanwhile, the second-1 anode Anode2-1 overlaps only the opening OP of the pixel defining layer 380 and does not overlap the pixel defining layer 380.

In an embodiment, the cathode has a step in a region overlapping the opening OP of the pixel defining layer 380, and has a low height at the center of the opening OP of the pixel defining layer 380 in FIG. 26. Additionally, a portion of the cathode included in the first-2 light emitting diode LD1-2 has a low height.

The remaining portion of the embodiment of FIGS. 27 and 28 may be the same as those described in FIGS. 9 and 10 and may also have a multi-resonance structure in which resonance structures of the first light emitting diode LD1 and the second light emitting diode LD2 have different thicknesses. Moreover, an effect of the multi-resonance structure described in FIGS. 11 to 20 may be similar.

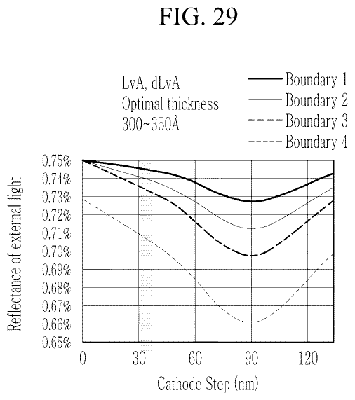

Additionally, the display quality may vary depending on the number of boundaries dividing the first light emitting diode LD1 and the second light emitting diode LD2, and this will be described in detail with reference to FIG. 29.

FIG. 29 illustrates a graph showing reflectance according to a step difference, according to an embodiment.

In an embodiment and referring to FIG. 14, the second anode Anode2 of the multi-resonance structure used in a simulation of FIG. 29 has a high luminance ratio (LvA) and has a thickness corresponding to a thickness range (about 300 Å or more and about 350 Å or less) where the rate of change of luminance (dLvA) is small.

In an embodiment, FIG. 29 shows a change in reflectance of external light according to a size of a step of a cathode that occurs at a corresponding boundary for a number of boundaries dividing the first light emitting diode LD1 and the second light emitting diode LD2, where the number of boundaries is 1, 2, 3, and 4. That is, in FIG. 29, when external light is incident, it may be seen to what extent the external light is reduced and reflected due to a destructive interference phenomenon of the multi-resonance structure.

In an embodiment and referring to FIG. 29, it may be seen that as a number of boundaries separating the first light emitting diode LD1 and the second light emitting diode LD2 increases, a degree to which external light is destroyed by destructive interference is large, so the reflectance of external light is reduced. In addition, it may be seen that the lowest reflectance of external light occurs when the size of the step occurring at the cathode is about 90 nm, and the largest destructive interference occurs when the step difference at the cathode is about 90 nm. However, considering that the step in the cathode occurs due to the thickness of the second anode Anode2, when the thickness value of the second anode Anode2 is about 300 Å or more and about 350 Å or less, the step in the cathode is about 90 nm—that is, it is difficult to have about 900 Å,so it may be difficult to form it by maximizing the reduction in reflectance. However, the step in the cathode may be adjusted to a step equivalent to about 90 nm by forming an additional structure and, according to another embodiment, if the refractive index of the second anode Anode2 is lowered by using another transparent electrode (e.g., an ITO, etc.) instead of an IZO, the optimal thickness of the second anode Anode2 may increase and reflectance of external light due to destructive interference may be lowered by adjusting the step in the cathode to a value equivalent to about 90 nm.

In the above, a structure of a single light emitting diode has been described, but in order to display one color, three colors of light emitting diodes may be required, and, in another embodiment, a different multi-resonance structure may be formed for each color of a light emitting diode. This embodiment will be described through FIG. 39.

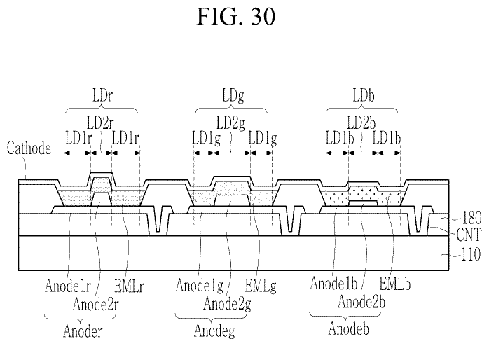

FIG. 30 illustrates a schematic cross-sectional view of an emissive display device, according to another embodiment.

FIG. 30 shows a cross-sectional structure of each of a red-light emitting diode LDr, a green-light emitting diode LDg, and a blue-light emitting diode LDb. In addition, in FIG. 30, a functional layer included in an intermediate layer is not shown, but light emitting layers EMLr, EMLg, and EMLb are shown.

In an embodiment, the red-light emitting diode LDr may include a red anode Anoder including a red first anode Anode1r and a red second anode Anode2r, a red-light emitting layer EMLr, and a cathode. The green-light emitting diode LDg may include a green anode Anodeg including a green first anode Anode1g and a green second anode Anode2g, a green-light emitting layer EMLg, and a cathode. The blue-light emitting diode LDb may include a blue anode Anodeb including a blue first anode Anode1b and a blue second anode Anode2b, a blue-light emitting layer EMLb, and a cathode.

In the embodiment of FIG. 30, the red second anode Anode2r has the narrowest width, the blue second anode Anode2b has a medium width, and the green second anode Anode2g has the largest width. Meanwhile, in terms of thickness, the red second anode Anode2r has the thickest thickness, the green second anode Anode2g has a medium thickness, and the blue second anode Anode2b has the smallest thickness. However, a height and a width may vary according to another embodiment.

Referring to the embodiment of FIG. 30, the anodes Anoder, Anodeg, and Anodeb, the light emitting layers EMLr, EMLg, and EMLb, and the cathodes may respectively constitute one light emitting diode LDr, LDg, and LDb, the light emitting diodes LDr, LDg, and LDb may respectively emit three different colors of light, showing that at least one of the three different second anodes Anode2r, Anode2g, and Anode2b included in the light emitting diodes LDr, LDg, and LDb may have different thicknesses or widths.

The embodiment of FIG. 30 may also be modified and, for example, may be formed into a modified structure as shown in FIGS. 25 to 28.

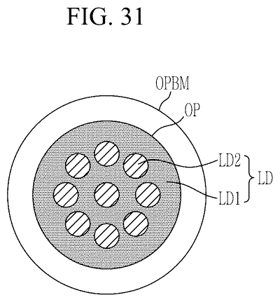

Hereinafter, more various modified structures will be described through FIGS. 31 to 34.

FIG. 31 to FIG. 34 illustrate a partial top plan view of an emissive display device, according to various embodiments.

FIG. 31 shows an embodiment in which a plurality of second light emitting diodes LD2 are formed within one light emitting diode.

In the embodiment of FIG. 31, a plurality of circular second light emitting diodes LD2 are separated and arranged within the first light emitting diode LD1, which is formed in a circular shape in a plan view. One second light emitting diode LD2 is positioned at a center of the first light emitting diode LD1, and eight second light emitting diodes LD2 are arranged along an imaginary circle around the first light emitting diode LD1. The plurality of second light emitting diodes LD2 are separately arranged, so that each second anode constituting the second light emitting diode LD2 may also be arranged separately from each other. According to another embodiment, a number and arrangement of the second light emitting diodes LD2 may vary. Referring to FIG. 31, one of the second anodes (also called the second center anode) is positioned while overlapping a center of the first anode, with a plurality of second anodes (also referred to as second peripheral anodes) arranged along a circular arc.

The above description focuses on an embodiment in which the first light emitting diode LD1 and the second light emitting diode LD2 are basically circular in a planar shape. However, according to another embodiment, they may have various planar shapes, so some embodiments including the first light emitting diode LD1 and the second light emitting diode LD2 having various planar shapes will be described through FIGS. 32A to 34.

FIGS. 32A, 32B and 32C shows an embodiment in which the first light emitting diode LD1 and the second light emitting diode LD2 have an oval shape.

FIGS. 32A, 32B and 32C shows an embodiment of a structure in which an elliptical second light emitting diode LD2 is positioned within an elliptical first light emitting diode LD1, where an elliptical long axis direction of the first light emitting diode LD1 may coincide with an elliptical long axis direction of the second light emitting diode LD2. Accordingly, the elliptical long axis direction of the opening OP of the pixel defining layer and the elliptical long axis direction of the second anode constituting the second light emitting diode LD2 may coincide with each other.

Additionally, FIGS. 32A, FIG. 32B, and FIG. 32C show separate structures with different long axis directions, where the long axis directions may be positioned at various angles other than the three directions shown in FIGS. 32A, 32B and 32C. In addition, according to another embodiment, a plurality of light emitting diodes LD having long axis directions are arranged in one display area to prevent display quality from changing depending on disposition of the long axis direction.

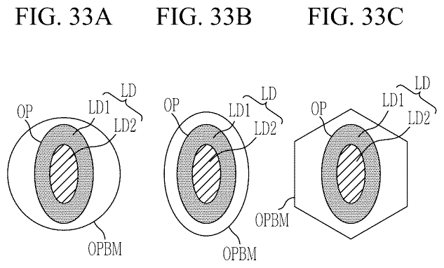

In FIGS. 32A, 32B and 32C, the opening OP of the pixel defining layer is shown, and a second opening of a light blocking layer (see OPBM in FIGS. 33A, 33B and 33C) is not shown. The opening of the light blocking layer may have various shapes such as a circle, so various embodiments including the opening of the light blocking layer may be as shown in FIGS. 33A, 33B and 33C.

In FIGS. 33A, 33B and 33C, various planar shapes of the second opening OPBM of the corresponding light blocking layer are shown when the elliptical long axis direction of the first light emitting diode LD1 and the elliptical long axis direction of the second light emitting diode LD2 coincide in the vertical direction, as shown in FIG. 32B.

In FIG. 33A, the second opening OPBM of the light blocking layer is formed in a circular shape, and in FIG. 33B, it has an elliptical shape, and has a long axis direction that matches the elliptical long axis direction of the first light emitting diode LD1 and the elliptical long axis direction of the second light emitting diode LD2. Moreover, in FIG. 33C, the second opening OPBM of the light blocking layer is formed in a hexagonal shape. In addition to the planar shape of the second opening OPBM of the light blocking layer shown in FIGS. 33A, 33B and 33C, it may have various planar shapes.

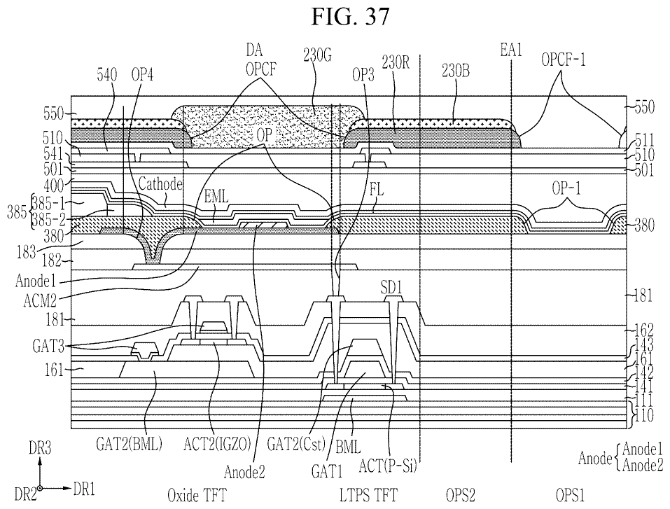

Referring to FIG. 33A, 33B and 33C, the shape of the second opening OPBM of the light blocking layer has the same planar shape or a different planar shape as or from that of the opening OP of the pixel defining layer and/or the planar shape of the second light emitting diode LD2. Meanwhile, in an embodiment and referring to FIG. 37, color filters of two or more colors may be overlapped to form a light blocking area of the color filters to replace the light blocking layer, and in this case, a second opening (see OPCF in FIG. 37) may be formed in the overlapped color filters. The second opening formed in the overlapped color filters may also have a planar shape that is the same as or different from the planar shape of the opening OP of the pixel defining layer and/or the planar shape of the second light emitting diode LD2.

In addition, in FIGS. 33A, 33B and 33C, in an embodiment, the entire opening OP of the pixel defining layer is shown to be positioned within the second opening OPBM of the light blocking layer. However, according to another embodiment, some of the openings OP of the pixel defining layer may be positioned outside the second opening OPBM of the light blocking layer, so that the openings OP of the pixel defining layer are obscured by the light blocking layer.

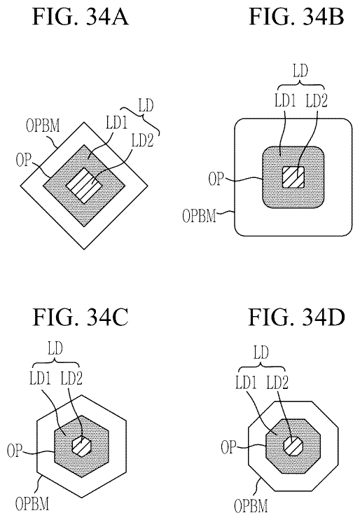

Furthermore, according to another embodiment, as shown in FIGS. 34A, 34B, 34C and 34D, the second opening OPBM of the light blocking layer, the opening OP of the pixel defining layer, the first light emitting diode LD1, and the second light emitting diode LD2 may be formed in a polygonal shape other than a circle or an oval.

In an embodiment and referring to FIG. 34A, the second opening OPBM of the light blocking layer, the opening OP of the pixel defining layer, the first light emitting diode LD1, and the second light emitting diode LD2 all have a diamond shape, and referring to FIG. 34B, the second opening OPBM of the light blocking layer, the opening OP of the pixel defining layer, the first light emitting diode LD1, and the second light emitting diode LD2 all have a chamfered quadrangular shape. In addition, referring to FIG. 34C, the second opening OPBM of the light blocking layer, the opening OP of the pixel defining layer, the first light emitting diode LD1, and the second light emitting diode LD2 all have a hexagonal shape, and referring to FIG. 34D, the second opening OPBM of the light blocking layer, the opening OP of the pixel defining layer, the first light emitting diode LD1, and the second light emitting diode LD2 all have an octagonal shape.

In FIGS. 34A, 34B, 34C and 34D, the second opening OPBM of the corresponding light blocking layer, the opening OP of the pixel defining layer, the first light emitting diode LD1, and the second light emitting diode LD2 all have the same planar shape, but may have different shapes, according to another embodiment. However, since the opening OP of the pixel defining layer and the first light emitting diode LD1 have the same boundary, they may have the same planar shape.

FIG. 32A to FIG. 34D show the second opening OPBM of the light blocking layer having various planar shapes, the opening OP of the pixel defining layer, the first light emitting diode LD1, and the second light emitting diode LD2, which may have a planar shape of a circle, an oval, or a polygon, and the second opening formed in the second anode and the overlapped color filters may also have a planar shape of a circle, an oval, or a polygon.

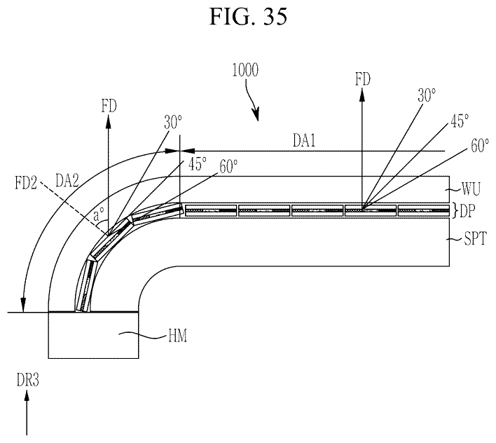

Hereinafter, a specific structure of the emissive display device will be described through FIG. 35 to FIG. 37, and first, a structural difference between the normal display area DA1 and the first bending display area DA2 will be described with reference to FIG. 35.

FIG. 35 illustrates a schematic cross-sectional view of a normal display area and a bending display area of the emissive display device of FIGS. 6 to 8, according to an embodiment.

In an embodiment and referring to FIG. 35, there is no structural difference between the normal display area DA1 and the first bending display area DA2, and directions of the light emitting layers included in the normal display area DA1 and the first bending display area DA2 may be different. That is, both the normal display area DA1 and the first bending display area DA2 have a support SPT disposed on a back surface, and a cover window WU disposed on a front surface. A housing HM may be positioned at one end and a back surface of the support SPT. However, an anode of the display panel DP included in the normal display area DA1 has a first normal direction FD, where the first normal direction FD has the same direction as the third direction DR3. Herein, the first normal direction FD corresponds to a front surface of the emissive display device 1000 and may hereinafter be referred to as a front direction. In contrast, an anode of the display panel DP included in the first bending display area DA2 has a direction that is different from the first normal direction FD, where one of the light emitting layers has a second normal direction FD2 and may have an angle difference a of a degree from the first normal direction FD corresponding to the front surface.

A user of the emissive display device 1000 sees an image from the front surface—that is, the first normal direction FD—so an image displayed in the first bending display area DA2 is also viewed based on the first normal direction FD, and a viewing angle of the emissive display device 1000 is measured based on the first normal direction FD. In FIG. 35, examples of viewing angles include about 30 degrees, about 45 degrees, and about 60 degrees.

Additionally, in order to improve visibility in the first bending display area DA2 based on the front surface—that is, the first normal direction FD—in the embodiment shown in FIG. 9, a position where the second anode Anode2 is positioned may be moved from the center to one side. In this case, a direction in which the second anode Anode2 moves may be directed away from the normal display area DA1 or in an opposite direction.

Hereinafter, a stacked structure of the display area DA and the first component area EA1 will be described in more detail through FIGS. 36 and 37.

FIG. 36 and FIG. 37 illustrate a cross-sectional view of an emissive display device, according to an embodiment.

FIG. 36 shows an embodiment including a light blocking layer 220, and FIG. 37 shows an embodiment in which the blue color filter 230B and the red color filter 230R are overlapped to form a light blocking area of the color filter instead of the light blocking layer 220.

An embodiment as shown in FIG. 36 will be described in detail.

In an embodiment, the emissive display device may be roughly divided into a lower panel layer and an upper panel layer, where the lower panel layer is a part where the light emitting diodes that constitute a pixel and the pixel circuit unit are positioned, and may include an encapsulation layer 400 that covers it. Here, the pixel circuit includes the second organic layer 182 and the third organic layer 183 and refers to the structure of the lower part, the light emitting diode may be an upper portion of the third organic layer 183 and is positioned on the bottom of the encapsulation layer 400. A structure positioned at an upper portion of the encapsulation layer 400 may correspond to the upper panel layer.

Referring to FIG. 36, a metal layer BML is disposed on the substrate 110.

In an embodiment, the substrate 110 may include a material that has a rigid property such as glass so as to not bend, or may include a flexible material that can be bent, such as plastic or a polyimide. In the case of a flexible substrate, as illustrated in FIG. 36, it may have a two-layer structure of a polyimide and a barrier layer formed of an inorganic insulating material on top of the polyimide.

In an embodiment, the metal layer BML may be formed in a position that overlaps a channel of the driving transistor in a plan view in a subsequent first semiconductor layer, and is also called a lower shielding layer. The metal layer BML may include a metal such as copper (Cu), molybdenum (Mo), aluminum (Al), or titanium (Ti), or a metal alloy thereof.

In an embodiment, a buffer layer 111 covering the substrate 110 and the metal layer BML is positioned on the substrate 110. The buffer layer 111 serves to block penetration of impure elements into a first semiconductor layer ACT (P-Si) and may be an inorganic insulating layer including silicon oxide (SiOx), silicon nitride (SiNx), silicon oxynitride (SiOxNy), or the like.

In an embodiment, the first semiconductor layer ACT (P-Si) formed of a silicon semiconductor (e.g., a polycrystalline semiconductor P-Si) is positioned on the buffer layer 111. The first semiconductor layer ACT (P-Si) includes a channel of a polycrystalline transistor LTPS TFT including the driving transistor, and a first region and a second region positioned at opposite sides. Herein, the polycrystalline transistor LTPS TFT may include not only the driving transistor but also various switching transistors or compensation transistors. In addition, a region having conductive layer characteristics may be provided at opposite sides of the channel of the first semiconductor layer ACT (P-Si) by plasma treatment or doping, thereby serving as a first electrode and a second electrode of a transistor.

In an embodiment, a first gate insulating layer 141 may be disposed on the first semiconductor layer ACT (p-Si). The first gate insulating layer 141 may include an inorganic insulating layer including silicon oxide (SiOx), silicon nitride (SiNx), silicon oxynitride (SiOxNy), or the like.

In an embodiment, a first gate conductive layer including a gate electrode of a polycrystalline transistor LTPS TFT may be positioned on the first gate insulating layer 141. The first gate conductive layer may also be formed with a first scan line or a light emission control line in addition to the gate electrode GAT1 of the polycrystalline transistor LTPS TFT. The first gate conductive layer may include a metal such as copper (Cu), molybdenum (Mo), aluminum (Al), titanium (Ti), or a metal alloy thereof, and may be configured as a single layer or multiple layers.

In an embodiment, after the first gate conductive layer is formed, plasma treatment or a doping process may be performed to make an exposed region of the first semiconductor layer conductive. That is, the first semiconductor layer ACT (P-Si) covered by the gate electrode GAT1 of the polycrystalline transistor LTPS TFT is not conductive, and a portion of the first semiconductor layer ACT (P-Si) that is not covered by the first gate conductive layer may have the same characteristic as the conductive layer.

In an embodiment, a second gate insulating layer 142 may be positioned on the first gate conductive layer and the first gate insulating layer 141 and may include an inorganic insulating layer including silicon oxide (SiOx), silicon nitride (SiNx), silicon oxynitride (SiONx), or the like.

In an embodiment, above the second gate insulating layer 142, a second gate conductive layer including a first electrode GAT2(Cst) of a storage capacitor Cst and a lower shielding layer GAT2(BML) of an oxide transistor Oxide TFT may be positioned. The lower shielding layer GAT2(BML) of the oxide transistor Oxide TFT may be positioned below the channel of the oxide transistor Oxide TFT to serve as shielding from light or electromagnetic interference provided to the channel from below. Meanwhile, the first electrode GAT2(Cst) of the storage capacitor Cst overlaps the gate electrode GAT1 of the driving transistor to form the storage capacitor Cst. According to another embodiment, the second gate conductive layer may further include a scan line, a control line, or a voltage line. The second gate conductive layer may include a metal such as copper (Cu), molybdenum (Mo), aluminum (Al), titanium (Ti), or a metal alloy thereof, and may be configured as a single layer or a multiple layer.

In an embodiment, a first interlayer insulating layer 161 may be disposed on the gate conductive layer, where the first interlayer insulating layer 161 may include an inorganic insulating layer including silicon oxide (SiOx), silicon nitride (SiNx), silicon oxynitride (SiOxNy), or the like, and according to an embodiment, an inorganic insulating material may be thickly formed.

In an embodiment, an oxide semiconductor layer ACT2(IGZO) including a channel, a first region, and a second region of an oxide transistor Oxide TFT may be positioned on the first interlayer insulating layer 161.

In an embodiment, a third gate insulating layer 143 may be disposed on the oxide semiconductor layer ACT2(IGZO) and may be positioned on the front side above the oxide semiconductor layer ACT2(IGZO) and the first interlayer insulating layer 161. The third gate insulating layer 143 may include an inorganic insulating layer including silicon oxide (SiOx), silicon nitride (SiNx), silicon oxynitride (SiONx), or the like.

In an embodiment, a third gate conductive layer GAT3 including a gate electrode of an oxide transistor Oxide TFT may be positioned on the third gate insulating layer 143, where the gate electrode of the oxide transistor Oxide TFT may overlap the channel. The third gate conductive layer GAT3 may further include a scan line or a control line and may additionally include a connection electrode connected to a lower shielding layer GAT2 (BML) of the oxide transistor Oxide TFT. The third gate conductive layer GAT3 may include a metal such as copper (Cu), molybdenum (Mo), aluminum (Al), titanium (Ti), or a metal alloy thereof, and it may be configured as a single layer or a multiple layer.

In an embodiment, a second interlayer insulating layer 162 may be disposed on the third gate conductive layer GAT3, where the second interlayer insulating layer 162 may have a single-or multi-layer structure. The second interlayer insulating layer 162 may include an inorganic insulating material such as silicon nitride (SiNx), silicon oxide (SiOx), and silicon oxynitride (SiOxNy), and may include an organic material, according to an embodiment.

In an embodiment, a first data conductive layer SD1 including a connection electrode that can be connected to first and second regions of each of the polycrystalline transistor LTPS TFT and the oxide transistor Oxide TFT may be positioned on the second interlayer insulating layer 162. A first data conductive layer SD1 may include a metal such as aluminum (Al), copper (Cu), molybdenum (Mo), titanium (Ti), or a metal alloy thereof, and may be configured as a single layer or a multiple layer.

In an embodiment, a first organic layer 181 may be disposed on the first data conductive layer SD1, where the first organic layer 181 may be an organic insulating layer containing an organic material, and where the organic material may include one or more materials of polyimide, polyamide, acrylic resin, benzocyclobutene, and phenol resin.

In an embodiment, a second data conductive layer including an anode connection electrode ACM2 may be disposed on the first organic layer 181, where the second data conductive layer may include a data line or a driving voltage line. A second data conductive layer SD2 may include a metal such as aluminum (Al), copper (Cu), molybdenum (Mo), titanium (Ti), or a metal alloy thereof, and may be configured as a single layer or a multiple layer.

In an embodiment, the second organic layer 182 and the third organic layer 183 are disposed on the second data conductive layer, and an opening OP4 for an anode connection is formed in the second organic layer 182 and the third organic layer 183. The anode connection electrode ACM2 is electrically connected to the anode through the anode connection opening OP4. The second organic layer 182 and the third organic layer 183 may be organic insulating layers, and may include one or more materials of polyimide, polyamide, acrylic resin, benzocyclobutene, and phenol resin. According to an embodiment, the third organic layer 183 may be omitted.

In an embodiment, the anode includes a first anode Anode1 and a second anode Anode2 positioned on the first anode Anode1 and overlapping a portion of the first anode Anode1. A position of the second anode Anode2 may be variously changed. The first anode Anode1 may be formed of a single layer including a transparent conductive oxide layer and a metal material, or a multiple layer including these, and the second anode Anode2 may be formed of a transparent conductive material. Herein, the transparent conductive oxide layer may include an indium tin oxide (ITO), a poly-ITO, an indium zinc oxide (IZO), an indium gallium zinc oxide (IGZO), and an indium tin zinc oxide (ITZO), and the metal material may include silver (Ag), molybdenum (Mo), copper (Cu), gold (Au), and aluminum (Al).

In an embodiment, a pixel defining layer 380 having an opening OP exposing the anode and covering at least a portion of the anode may be positioned on the anode. The pixel defining layer 380 may be a black pixel defining layer formed of an organic material having a black color so that light applied from the outside is not reflected back to the outside, and may be formed of a transparent organic material, according to an embodiment. Therefore, according to another embodiment, the pixel defining layer 380 may include a negative type of black organic material and may include a black pigment.

In an embodiment, a spacer 385 may be positioned on the pixel defining layer 380, where the spacer 385 may include a first portion 385-1 of the spacer positioned in a high and narrow region and a second portion 385-2 of the spacer positioned in a low and wide region. Unlike the pixel defining layer 380, the spacer 385 may be formed of a transparent organic insulating material. According to an embodiment, the spacer 385 may be formed of a positive-type transparent organic material.

In an embodiment, a functional layer FL and a cathode may be sequentially positioned on the anode, the spacer 385, and the pixel defining layer 380, where the functional layer FL and the cathode may be positioned throughout the display area DA and the first component area EA1. A light emitting layer EML is positioned between the function layer FL, and the light emitting layer EML may be positioned only within the opening OP of the pixel defining layer 380. Hereinafter, the functional layer FL and the light emitting layer EML may be referred to as an intermediate layer. The functional layer FL may include at least one layer among auxiliary layers such as an electron injection layer, an electron transport layer, a hole transport layer, and a hole injection layer, where the hole injection layer and the hole transport layer may be positioned below the light emitting layer EML, and where the electron transport layer and the electron injection layer may be positioned at an upper portion of the light emitting layer EML.

The cathode may have a step due to the second anode Anode2 of the anode.

In an embodiment, an encapsulation layer 400 is disposed on the cathode and may include at least one inorganic layer and at least one organic layer, and may have a triple-layer structure including a first inorganic encapsulation layer, an organic encapsulation layer, and a second inorganic encapsulation layer. The encapsulation layer 400 may serve to protect the light emitting layer EML from moisture or oxygen that may be introduced from the outside. According to an embodiment, the encapsulation layer 400 may include a structure in which an inorganic layer and an organic layer are further sequentially stacked.

In an embodiment, on the encapsulation layer 400, sensing insulating layers 501, 510, and 511 and a plurality of sensing electrodes 540 and 541 are positioned for touch detection. In the embodiment of FIG. 36, touch may be sensed in a capacitive manner using the two sensing electrodes 540 and 541.

In an embodiment, a first sensing insulating layer 501 is disposed on the encapsulation layer 400, and the sensing electrodes 540 and 541 are positioned thereon. The plurality of sensing electrodes 540 and 541 may be insulated with the second sensing insulating layer 510 provided therebetween, some of which may be electrically connected through an opening positioned in the second sensing insulating layer 510. Here, the sensing electrodes 540 and 541 may include a metal such as aluminum (Al), copper (Cu), silver (Ag), gold (Au), molybdenum (Mo), titanium (Ti), and tantalum (Ta), or the like or a metal alloy thereof, and may be formed of a single layer or a multiple layer. The third sensing insulating layer 511 is disposed on the sensing electrode 540.

In an embodiment, the light blocking layer 220 and the color filter 230 are positioned on the third sensing layer 511. The color filter 230 may be one of the red color filter, the green color filter and the blue color filter.

In an embodiment, the light blocking layer 220 may be positioned to overlap the sensing electrodes 540 and 541 in a plan view, where the light blocking layer 220 has a second opening OPBM, and where the second opening OPBM of the light blocking layer 220 overlaps the opening OP of the pixel defining layer 380 in a plan view. Additionally, the second opening OPBM of the light blocking layer 220 may be formed wider than the opening OP of the pixel defining layer 380. As a result, the anode overlapping the opening OP of the pixel defining layer 380 (that is, exposed by the opening OP of the pixel defining layer 380) may also have a structure that is not obscured by the light blocking layer 220 in a plan view. This is to ensure that the anode and the light emitting layer EML capable of displaying an image are not obscured by the light blocking layer 220 and the sensing electrodes 540 and 541. In addition, the light blocking layer 220 has a structure that overlaps the anode connection opening OP4 in a plan view, but that does not overlap the opening OP3 of the first organic layer 181 in a plan view.

In an embodiment, the color filter 230 is positioned above the sensing insulating layers 501, 510, and 511 and the light blocking layer 220. According to an embodiment, the color filter 230 may be replaced with a color conversion layer or may further include a color conversion layer. The color conversion layer may include a quantum dot.

In an embodiment, a planarization layer 550 may be disposed on the color filter 230 to cover the color filter 230, and according to another embodiment, a low-refraction layer and an additional planarization layer may be further positioned on the planarization layer 550 to improve frontal visibility and light output efficiency of the display device. Light may be refracted and emitted toward the front by a low-refractive layer and an additional planarization layer with a high-refractive characteristic. In this case, according to another embodiment, the planarization layer 550 may be omitted and a low-refractive layer and an additional planarization layer may be positioned directly on the color filter 230.

In an embodiment, a polarizer is not included at an upper portion of the planarization layer 550. In other words, the polarizer may play a role in preventing external light from being incident and reflected from the anode, etc., and degrading the display when viewed by a user. However, in an embodiment, a structure is already included in which a side surface of the anode is covered with the pixel defining layer 380 to reduce the degree of reflection from the anode, and the light blocking layer 220 is also formed to reduce the degree of incident light, preventing deterioration of display quality due to reflection. Accordingly, there is no need to separately form a polarizer on a front surface of the display panel DP.

Additionally, in FIG. 36, in addition to the stacked structure of the display area DA, a cross-sectional structure of the first component area EA1 that is formed to allow light to transmit through a portion of the display area DA is shown.

In FIG. 36, the first component area EA1 is divided into a first optical sensor area OPS1 (also referred to as a transmissive optical sensor area) and a second optical sensor area OPS2 (also referred to as a non-transmissive optical sensor area). Here, the first optical sensor area OPS1 is an area formed to allow light to pass through it because additional openings OP-1 and OPBM-1 are positioned so as not to overlap the pixel defining layer 380 and the light blocking layer 220 in a plan view. In contrast, the second optical sensor area OPS2 is an area formed to overlap the pixel defining layer 380 and the light blocking layer 220 in a plan view so that light does not transmit through. Both the first optical sensor area OPS1 and the second optical sensor area OPS2 of the first component area EA1 may not include a layer that blocks light, such as a metal layer or a semiconductor layer. For reference, the first optical element ES1 (see FIG. 2) is positioned on a back surface of the first component area EA1, and a front surface of the emissive display device may be detected through the first optical sensor area OPS1 positioned in the first component area EA1.

Specifically, a layered structure of the first component area EA1 is as follows.

In an embodiment, the buffer layer 111, which is an inorganic insulating layer, is positioned on the substrate 110, and the first gate insulating layer 141 and the second gate insulating layer 142, which are inorganic insulating layers, are sequentially positioned thereon. Additionally, a first interlayer insulating layer 161, a third gate insulating layer 143, and a second interlayer insulating layer 162, which are inorganic insulating layers, are sequentially stacked on the second gate insulating layer 142.

In an embodiment, on the second interlayer insulating layer 162, a first organic layer 181, a second organic layer 182, and a third organic layer 183, which are organic insulating layers, are sequentially stacked.

In an embodiment, a functional layer FL may be positioned on the third organic layer 183, and a cathode may be positioned on the third organic layer 183.

In an embodiment, an encapsulation layer 400 is disposed on the cathode, and sensing insulating layers 501, 510, and 511 are positioned sequentially on the cathode. The encapsulation layer 400 may have a triple-layer structure sequentially including an inorganic encapsulation layer, an organic encapsulation layer, and an inorganic encapsulation layer. Additionally, the sensing insulating layers 501, 510, and 511 may all be inorganic insulating layers.

In an embodiment, a planarization layer 550 may be disposed on the sensing insulating layers 501, 510, and 511.

In an embodiment, the first component area EA1 as described above does not include a metal layer, a first semiconductor layer, a first gate conductive layer, a second gate conductive layer, an oxide semiconductor layer, a third gate conductive layer, a first data conductive layer, a second data conductive layer, and an anode. Additionally, the light emitting layer EML and the sensing electrodes 540 and 541 are not formed.

In addition, in the first optical sensor area OPS1 of the first component area EA1, additional openings OP-1 and OPBM-1 are formed in the pixel defining layer 380 and the light blocking layer 220, respectively, so that the pixel defining layer 380 and the light blocking layer 220 may not be formed. As a result, light may pass through the first optical sensor area OPS1. Moreover, in an embodiment, the second optical sensor area OPS2 of the first component area EA1 may not have additional openings OP-1 and OPBM-1, so it may have a structure that does not transmit light by overlapping the pixel defining layer 380 and the light blocking layer 220.

In the above, an embodiment in which a total of three organic layers are formed, and an anode connection opening is formed in the second organic layer and the third organic layer has been described. However, the organic layer may be formed of at least two layers, and in this case, the anode connection opening may be positioned in the upper organic layer positioned away from the substrate, and a lower organic layer opening may be positioned in the lower organic layer.

Meanwhile, below, through FIG. 37, an embodiment in which two or more color filters are formed by overlapping each other instead of the light blocking layer 220 has been described, and in FIG. 37, an embodiment in which the light blocking area of the color filter is formed by overlapping the blue color filter 230B and the red color filter 230R will be described in detail.

In an embodiment and referring to FIG. 37, the third sensing insulating layer 511 and the structure below it are the same as those in FIG. 36, so only an upper structure of the third sensing insulating layer 511, which differs from that in FIG. 36, will be described in detail as follows.

In an embodiment, the color filters 230R, 230G, and 230B are positioned on the third sensing insulating layer 511. The light blocking layer is not included, and the role of the light blocking layer is performed by the overlapped color filters 230R and 230B, where the overlapped color filters 230R and 230B may be positioned to overlap the sensing electrodes 540 and 541 in a plan view. The overlapped color filters 230R and 230B have a second opening OPCF, where the second opening OPCF of the overlapped color filters 230R and 230B overlaps the opening OP of the pixel defining layer 380 in a plan view. Additionally, the second opening OPCF of the overlapped color filters 230R and 230B may be wider than the opening OP of the pixel defining layer 380. As a result, the anode overlapping the opening OP of the pixel defining layer 380 (that is, exposed by the opening OP of the pixel defining layer 380) may also have a structure that is not obscured by the overlapped color filters 230R and 230B in a plan view. This is to ensure that the anode and the light emitting layer EML capable of displaying an image are not obscured by the overlapped color filters 230R and 230B and the sensing electrodes 540 and 541. In addition, the overlapped color filters 230R and 230B have a structure that overlaps the anode connection opening OP4 in a plan view.

In an embodiment, within the second opening OPCF of the overlapped color filters 230R and 230B, a single color filter may be positioned and in FIG. 37, the green color filter 230G is positioned. According to an embodiment, the color filters 230R, 230G, and 230B may be replaced with a color conversion layer or it may further include a color conversion layer. The color conversion layer may include a quantum dot.

In an embodiment, a planarization layer 550 may be disposed on the color filters 230R, 230G, and 230B to cover the color filters 230R, 230G, and 230B, and according to another embodiment, a low-refraction layer and an additional planarization layer may be further positioned on the planarization layer 550 to improve front visibility and light output efficiency of the display device. According to another embodiment, the planarization layer 550 may be omitted and a low-refractive layer and an additional planarization layer may be positioned directly on the color filter.

In the embodiment of FIG. 37, the polarizer is not included at an upper portion of the planarization layer 550. In other words, the polarizer may play a role in preventing external light from being incident and reflected from the anode, etc., and degrading the display when viewed by a user. However, in an embodiment, a structure is already included, in which a side surface of the anode is covered with the pixel defining layer 380 to reduce a degree of reflection from the anode, and the overlapped color filters 230R and 230B are also formed to reduce the degree of incident light, preventing deterioration of display quality due to reflection. Accordingly, there is no need to separately form a polarizer on a front surface of the display panel DP.

Furthermore, a cross-sectional structure of the first component area EA1 according to the embodiment of FIG. 37 may be as follows.

In an embodiment, the first component area EA1 is divided into a first optical sensor area OPS1 and a second optical sensor area OPS2. Herein, the first optical sensor area OPS1 is an area formed to allow light to pass through it because additional openings OP-1 and OPCF-1 are positioned so as not to overlap a light blocking area of the color filter, which is formed by overlapping the pixel defining layer 380 and at least two color filters, in a plan view. In contrast, the second optical sensor area OPS2 is an area formed to prevent light from being transmitted by overlapping in a plan view the light blocking area of the color filter formed by overlapping the pixel defining layer 380 and at least two color filters. Both the first optical sensor area OPS1 and the second optical sensor area OPS2 of the first component area EA1 may not include a layer that blocks light, such as a metal layer or a semiconductor layer. For reference, the first optical element ES1 (see FIG. 2) is positioned on a back surface of the first component area EA1, and a front surface of the emissive display device may be detected through the first optical sensor area OPS1 positioned in the first component area EA1.

Specifically, a layered structure of the first component area EA1 is as follows.

In an embodiment, the buffer layer 111, which is an inorganic insulating layer, is positioned on the substrate 110, and the first gate insulating layer 141 and the second gate insulating layer 142, which are inorganic insulating layers, are sequentially positioned thereon. Additionally, a first interlayer insulating layer 161, a third gate insulating layer 143, and a second interlayer insulating layer 162, which are inorganic insulating layers, are sequentially stacked on the second gate insulating layer 142.

In an embodiment, on the second interlayer insulating layer 162, the first organic layer 181, the second organic layer 182, and the third organic layer 183, which are organic insulating layers, are sequentially stacked.

In an embodiment, the functional layer FL may be positioned on the third organic layer 183, and a cathode may be positioned on the third organic layer 183.

In an embodiment, the encapsulation layer 400 is disposed on the cathode, and sensing insulating layers 501, 510, and 511 are positioned sequentially on the cathode. The encapsulation layer 400 may have a triple-layer structure sequentially including an inorganic encapsulation layer, an organic encapsulation layer, and an inorganic encapsulation layer. Additionally, the sensing insulating layers 501, 510, and 511 may all be inorganic insulating layers.

In an embodiment, the planarization layer 550 may be disposed on the sensing insulating layers 501, 510, and 511.

In an embodiment, the first component area EA1 as described above does not include a metal layer, a first semiconductor layer, a first gate conductive layer, a second gate conductive layer, an oxide semiconductor layer, a third gate conductive layer, a first data conductive layer, and a second data conductive layer and an anode. Additionally, the light emitting layer EML and the sensing electrodes 540 and 541 are not formed.

In addition, in an embodiment, in the first optical sensor area OPS1 of the first component area EA1 and the additional openings OP-1 and OPCF-1 may be formed in the pixel defining layer 380 and the light blocking area of the color filter, respectively, so that the pixel defining layer 380 and the color filter may not be formed. As a result, light may pass through the first optical sensor area OPS1. On the other hand, the second optical sensor area OPS2 of the first component area EA1 may not have additional openings OP-1 and OPCF-1, so it may have a structure that does not transmit light by overlapping the pixel defining layer 380 and the light blocking area of the color filter.

In the above, one or more embodiments in which a total of three organic layers are formed, and an anode connection opening is formed in the second organic layer and the third organic layer has been described. However, the organic layer may be formed of at least two layers, and in this case, the anode connection opening may be positioned in the upper organic layer positioned away from the substrate, and a lower organic layer opening may be positioned in the lower organic layer.

While this disclosure has been described in connection with what is presently considered to be practical embodiments, it is to be understood that the disclosure is not limited to the disclosed embodiments, but, is intended to cover various modifications and equivalent dispositions included within the spirit and scope of the invention. Moreover, although embodiments have been described in detail above, the scope of the invention is not limited thereto, and various modifications and improvements made by those skilled in the art using the basic concepts of the invention. Therefore, the scope of the invention is not limited to the contents described in the detailed description of the specification. Moreover, the embodiments or parts of the embodiments may be combined in whole or in part without departing from the scope of the invention.

What is claimed is:

1. An emissive display device comprising:
a substrate, wherein the substrate is a flexible substrate;
an anode positioned on the substrate;
a pixel defining layer configured to have a first opening overlapping the anode;
a light emitting layer positioned within the first opening of the pixel defining layer; and
a cathode positioned on the light emitting layer and the pixel defining layer,
wherein the anode includes,
a first anode, which is a reflective electrode; and
a second anode, which is a transparent electrode positioned on the first anode and which includes a second anode planar area,
wherein the second anode planar area is smaller than a first node planar area in a region overlapping the first opening of the pixel defining layer, and
wherein the second anode has a planar structure that is symmetrical with respect to a center of the first opening of the pixel defining layer.

2. The emissive display device of claim 1, wherein
the second anode is in direct contact with a portion of the first anode.

3. The emissive display device of claim 2, wherein
the second anode overlaps the center of the first opening of the pixel defining layer.

4. The emissive display device of claim 3, wherein
a center of the second anode is aligned with the center of the first opening of the pixel defining layer.

5. The emissive display device of claim 1, wherein
the first anode includes a metal material, and
the second anode includes a metal oxide.

6. The emissive display device of claim 5, wherein
the second anode has a thickness of about 50 Å or more and about 500 Å or less.

7. The emissive display device of claim 1, wherein
the cathode has a step in an area overlapping the first opening.

8. The emissive display device of claim 1, wherein
the second anode overlaps the first opening and does not overlap the pixel defining layer.

9. The emissive display device of claim 1, wherein
at least a portion of the second anode is covered by a portion of the pixel defining layer.

10. The emissive display device of claim 1, further comprising:
an encapsulation layer disposed on the cathode; and
a light blocking layer or a plurality of color filters positioned on the encapsulation layer and configured to have a second opening that overlaps the first opening in a plan view,
wherein the second opening and the first opening have a same planar shape.

11. The emissive display device of claim 1, further comprising:
an encapsulation layer disposed on the cathode; and
a light blocking layer or a plurality of color filters positioned on the encapsulation layer and configured to have a second opening that overlaps the first opening in a plan view,
wherein the second opening and the first opening have different planar shapes.

12. The emissive display device of claim 1, wherein
the first opening has one of a circular shape, an oval shape, and a polygonal shape.

13. The emissive display device of claim 12, wherein
the first opening and the second anode are each formed in an oval shape, wherein
an oval long axis direction of the first opening coincides with an oval long axis direction of the second anode.

14. The emissive display device of claim 1, wherein
the second anode includes a plurality of second anodes, wherein the plurality of second anodes are disposed apart from each other.

15. The emissive display device of claim 14, wherein
the plurality of second anodes, which are disposed apart from each other, have a same thickness in an area overlapping the first opening.

16. The emissive display device of claim 14, wherein
a first one of the plurality of second anodes is positioned at a center of the first opening, and a second one of the plurality of second anodes is positioned along an imaginary circle positioned around the first one of the plurality of second anodes.

17. The emissive display device of claim 1, wherein
the anode, the light emitting layer, and the cathode constitute one light emitting diode,
wherein the light emitting diode includes a first light emitting diode and a second light emitting diode that emit light of different colors, and
wherein a second anode included in the first light emitting diode has a different thickness or width than that of a second anode included in the second light emitting diode.

18. The emissive display device of claim 17, wherein
an area ratio of an area of the second anode to an area of the first anode included in each of the first light emitting diode and the second light emitting diode is about 0.9 times or more and about 1.1 times or less.

19. An emissive display device comprising:
a substrate;
an anode positioned on the substrate and configured to include a first anode and a second anode;
a pixel defining layer configured to have a first opening overlapping the anode;
a light emitting layer positioned within the first opening of the pixel defining layer; and
a cathode positioned on the light emitting layer and the pixel defining layer,
wherein the first anode is a reflective electrode, and the second anode is a transparent electrode, wherein
the second anode is positioned on the first anode to be in direct contact with the first anode,
a portion of the second anode overlaps the pixel defining layer, and
a portion of the first anode is not covered by the second anode in an area overlapping the first opening of the pixel defining layer.

20. The emissive display device of claim 19, wherein
the second anode does not overlap a center of the first opening of the pixel defining layer.

21. The emissive display device of claim 20, wherein
the cathode has a step in an area overlapping the first opening.

22. The emissive display device of claim 19, wherein
the second anode includes two or more second anodes that are disposed apart from each other.

23. The emissive display device of claim 19, wherein
the second anode has a thickness of about 50 Å or more and about 500 Å or less.

24. The emissive display device of claim 19, wherein
the second anode has a planar structure that is symmetrical with respect to a center of the first opening of the pixel defining layer.

25. An electronic device comprising:
an emissive display device,
where the emissive display device comprises:
a substrate, wherein the substrate is a flexible substrate;
an anode positioned on the substrate;
a pixel defining layer configured to have a first opening overlapping the anode;
a light emitting layer positioned within the first opening of the pixel defining layer; and
a cathode positioned on the light emitting layer and the pixel defining layer,
wherein the anode includes,
a first anode, which is a reflective electrode; and
a second anode, which is a transparent electrode positioned on the first anode and which includes a second anode planar area,
wherein the second anode planar area is smaller than a first node planar area in a region overlapping the first opening of the pixel defining layer, and
wherein the second anode has a planar structure that is symmetrical with respect to a center of the first opening of the pixel defining layer.

26. An electronic device comprising:
an emissive display device,
wherein the emissive display device comprises:
a substrate;
an anode positioned on the substrate and configured to include a first anode and a second anode;
a pixel defining layer configured to have a first opening overlapping the anode;
a light emitting layer positioned within the first opening of the pixel defining layer; and
a cathode positioned on the light emitting layer and the pixel defining layer,
wherein the first anode is a reflective electrode, and the second anode is a transparent electrode, wherein
the second anode is positioned on the first anode to be in direct contact with the first anode,
a portion of the second anode overlaps the pixel defining layer, and
a portion of the first anode is not covered by the second anode in an area overlapping the first opening of the pixel defining layer.
